(19) United States
(12) Patent Application Publication
(10) Pub. No.: US 2025/0282994 A1
(43) Pub. Date: Sep. 11, 2025

(54) ETCHING COMPOSITIONS, METHODS OF TREATING SUBSTRATES USING THE SAME, AND METHODS OF MANUFACTURING INTEGRATED CIRCUIT DEVICES USING THE SAME

(71) Applicant: Samsung Electronics Co., Ltd., Suwon-si (KR)

(72) Inventors: Jinhye Bae, Suwon-si (KR); Geunjoo Baek, Cheonan-si (KR); Mihyun Park, Suwon-si (KR); Dai Hyun Kim, Suwon-si (KR); Sangmoon Yun, Cheonan-si (KR); Chisung Ihn, Cheonan-si (KR); DongHoon Ha, Suwon-si (KR)

(73) Assignee: Samyoung Pure Chemicals Co., Ltd., Cheonan-si (KR)

(21) Appl. No.: 18/947,090

(22) Filed: Nov. 14, 2024

(30) Foreign Application Priority Data
Mar. 6, 2024 (KR) 10-2024-0032172

(51) Int. Cl. C09K 13/08; H01L 21/306

(52) U.S. Cl. CPC C09K 13/08; H01L 21/30604; H01L 21/30625

(57) ABSTRACT

Disclosed is an etching composition for etching a silicon layer, the etching composition including an acid mixture including hydrofluoric acid, nitric acid, phosphoric acid, and acetic acid, a reaction initiator that initiates a reaction between the silicon layer and the acid mixture and includes a reducing organic compound, and water.

### CROSS-REFERENCE TO RELATED APPLICATION

This application claims priority under 35 U.S.C. § 119 to Korean Patent Application No. 10-2024-0032172, filed on Mar. 6, 2024, in the Korean Intellectual Property Office, the disclosure of which is incorporated by reference herein in its entirety.

### BACKGROUND

Embodiments of the present disclosure described herein relate to an etching composition, a method of treating a substrate using the same, and a method of manufacturing an integrated circuit device using the same.

In a process of manufacturing an integrated circuit device, a silicon substrate is frequently used to achieve high integration of the integrated circuit device. In particular, the integrated circuit device may be formed on a structure including an epitaxial layer obtained by growing a crystalline material on a silicon layer, using the structure. In this case, an etching composition that may selectively remove the silicon layer without damaging the epitaxial layer is required. Further, the etching composition is required to be able to efficiently etch the silicon layer through rapid reaction initiation.

### SUMMARY

Embodiments of the present disclosure provide an etching composition used when a silicon substrate is etched.

Embodiments of the present disclosure also provide an etching composition having an improved etching reaction initiation rate of a silicon substrate.

Embodiments of the present disclosure also provide an etching composition having a high selectivity for different silicon layers during an etching reaction.

Embodiments of the present disclosure also provide a method of treating a silicon substrate using the etching composition, and a method of manufacturing an integrated circuit device using the same.

According to an embodiment, an etching composition for etching a silicon layer includes an acid mixture including hydrofluoric acid, nitric acid, phosphoric acid, and acetic acid, a reaction initiator that initiates a reaction between the silicon layer and the acid mixture and includes a reducing organic compound, and water.

In some embodiments of the present disclosure, the reaction initiator may reduce the nitric acid to nitrous acid, e.g., is capable of reducing the nitric acid to nitrous acid.

In some embodiments of the present disclosure, the reducing organic compound may include a reducing sugar, an organic acid compound, a phenol compound, a thiol compound, a disulfide compound, a hydroxylamine compound, or combinations thereof.

In some embodiments of the present disclosure, the organic acid compound may include an ascorbic acid, an ascorbyl palmitate, an ascorbyl glucoside, a sodium ascorbate, a potassium ascorbate, a calcium ascorbate, an erythorbic acid, a fumaric acid, a lactic acid, a citric acid, a malic acid, a butyric acid, a formic acid, a methanoic acid, an ethanoic acid, a propionic acid, a butanoic acid, a pentanoic acid, or combinations thereof.

In some embodiments of the present disclosure, the reducing sugar may include glyceraldehyde, erythrose, ribose, xylose, arabinose, ribulose, glucose, fructose, mannose, galactose, maltose, lactose, cellobiose, dextrin, or combinations thereof.

In some embodiments of the present disclosure, the phenol compound may include phenol, pyrocatechol, a caffeic acid, a protocatechuic acid, a ferulic acid, hydroquinone, pyrogallol, a gallic acid, propyl gallate, or combinations thereof.

In some embodiments of the present disclosure, the thiol compound may include cysteine, benzylmercaptan, 2-mercaptopyridine, benzothiazole-2-thiol, gamma-glutamylcysteine, 1-phenyl-5-mercaptotetrazole, glutathione, a mercaptopropionic acid, a mercaptoacetic acid, 2-mercaptobenzimidazole, 2-mercaptobenzothiazole, 2-mercapto-1methylimidazole, or combinations thereof.

In some embodiments of the present disclosure, the disulfide compound may include cystine, dibenzyl disulfide, dipyridyl disulfide, dibenzothiazyl sulfide, thiamine disulfide, allitiamine, fursultiamine, diallyl disulfide, bis(2-methyl-3-furyl)disulfide, oxidized glutathione, or combinations thereof.

In some embodiments of the present disclosure, the etching composition may contain 10 wt % to 30 wt % of the nitric acid, 0.5 wt % to 15 wt % of the hydrofluoric acid, 0.1 wt % to 30 wt % of the phosphoric acid, 10 wt % to 50 wt % of the acetic acid; 0.01 wt % to 3 wt % of the reaction initiator, and a remaining balance of water.

In some embodiments of the present disclosure, the etching composition may further contain 0.5 wt % to 10 wt % of a nitrogen compound.

In some embodiments of the present disclosure, the nitrogen compound may include an ammonium compound, urea, a urea derivative, an azole compound, or combinations thereof.

An embodiment of the present disclosure may include a method of treating a silicon substrate using the etching composition. According to an embodiment, a method of treating the silicon substrate includes preparing a silicon substrate on which a first silicon layer doped with impurities at a first doping concentration and a second silicon layer provided as an epitaxial layer and doped with impurities at a second doping concentration different from the first doping concentration are laminated, and selectively etching the first silicon layer with an etching composition.

In some embodiments of the present disclosure, the first doping concentration may be greater than the second doping concentration.

In some embodiments of the present disclosure, the method may further include removing a portion of the first silicon layer through chemical mechanical polishing before the first silicon layer is removed through the etching composition.

In some embodiments of the present disclosure, the method may further include removing a portion of the second silicon layer through chemical mechanical polishing after the first silicon layer is removed through the etching composition.

An embodiment of the present disclosure may include a method of manufacturing an integrated circuit device using the etching composition. According to an embodiment, a method of manufacturing an integrated circuit device includes preparing a silicon substrate including a first silicon layer doped with impurities at a first doping concentration and a second silicon layer doped with impurities at a second doping concentration and having a rear surface close to the first silicon layer and a front surface close to the second silicon layer, forming a first device pattern on the front surface of the silicon substrate, selectively etching and removing the first silicon layer through the etching composition, and forming a second device pattern on the rear surface from which the first silicon layer is removed.

In some embodiments of the present disclosure, the preparing of the silicon substrate may include forming a through-substrate via formed from an upper surface of the second silicon layer at a predetermined depth.

In some embodiments of the present disclosure, the second device pattern may include a power delivery network that supplies power to a device part.

### BRIEF DESCRIPTION OF THE FIGURES

The above and other objects and features of the present disclosure will become apparent by describing in detail embodiments thereof with reference to the accompanying drawings.

FIG. 1 is a flowchart illustrating an example method of treating a silicon substrate using an etching composition according to an embodiment of the present disclosure.

FIGS. 2A to 2C are cross-sectional views sequentially describing an example process of treating the silicon substrate using an etching composition according to some embodiments of the present disclosure.

FIG. 3 is a flowchart illustrating an example method of treating the silicon substrate according to some embodiments of the present disclosure.

FIGS. 4A to 4E are cross-sectional views sequentially describing an example process of treating the silicon substrate according to some embodiments of the present disclosure.

FIG. 5A is a cross-sectional view conceptually illustrating a semiconductor chip that may be manufactured using the process of treating the silicon substrate according to some embodiments of the present disclosure, and FIG. 5B is an enlarged cross-sectional view of a part corresponding to P1 in FIG. 5A.

FIGS. 6A to 6F are illustrative cross-sectional views sequentially illustrating an example method of manufacturing the IC device according to some embodiments of the present disclosure.

FIGS. 7A to 7D are images obtained by photographing a surface of the silicon substrate when etching is performed using an etching composition according to a comparative example (7A, 7B) and a composition according to an example embodiment (7C, 7D).

FIGS. 8A to 8D are images illustrating a height of the surface of the silicon substrate when the etching is performed using the etching composition according to the comparative example and the composition according to an example embodiment of FIGS. 7A to 7D.

FIG. 9 is a graph depicting a thickness of a silicon layer of a substrate remaining after the etching when the etching is performed using the etching composition according to the comparative examples 1 and 2 and the composition according to an example embodiment.

### DETAILED DESCRIPTION

Since the present disclosure may be variously modified and have various forms, an embodiment thereof will be illustrated in the drawings and will herein be described in detail. However, it should be understood that the present disclosure is not limited to a specific disclosure and includes all changes, equivalents, and substitutes included in the spirit and scope of the present disclosure.

An etching composition according to some embodiments of the present disclosure is an etching composition for etching a silicon layer and includes an acid mixture that reacts with the silicon layer, a reaction initiator that initiates a reaction between the silicon layer and the acid mixture, and water. The acid mixture may include a nitric acid, a hydrofluoric acid, a phosphoric acid, and an acetic acid.

In some embodiments of the present disclosure, the nitric acid and the hydrofluoric acid included in the etching composition are main components that etch the silicon layer through a silicon oxidation reaction by the nitric acid and dissociation of a silicon oxide by the hydrofluoric acid. This etching reaction of the nitric acid and the hydrofluoric acid is performed at a relatively fast rate (e.g., several microns per minute), making it easy to etch and remove the silicon layer.

The reaction of the nitric acid and the hydrofluoric acid on the silicon layer may be expressed by Chemical Formula 1.

3Si+4HNO₃→3SiO₂+4NO₂+2H₂O

3SiO₂+6HF→H₂SiF₆+2H₂O [Chemical Formula 1]

In Chemical Formula 1, the nitric acid reacts with the silicon layer, which is an etching target, to provide the silicon oxide as a result. A mechanism in which silicon is oxidized by the nitric acid may be expressed by Chemical Formula 2.

Si+4HNO₃→SiO₂+4NO+2H₂O

HNO₃+2NO+H₂O→3HNO₂

Si+4HNO₂→SiO₂+2H₂O+4NO [Chemical Formula 2]

In Chemical Formula 2, a) the nitric acid (HNO₃) reacts with the silicon to form a silicon oxide (SiO₂) and a nitric oxide (NO); b) the nitric acid reacts with the nitric oxide to form a nitrous acid (HNO₂); c) the nitrous acid also reacts with the silicon to form the silicon oxide.

The nitrous acid is a stronger oxidizing agent than the nitric acid, more easily generates an oxidation reaction of the silicon than the nitric acid, and has a very fast speed for the oxidation reaction. In some embodiments, operation c) is an operation that reacts relatively faster than operation a). The reaction initiator that may reduce the nitric acid to the nitrous acid is included such that the present disclosure proceeds to operation c) in which the oxidation reaction of the silicon is relatively quick. In some embodiments, the reaction initiator provides electrons to the nitric acid to reduce the nitric acid to the nitrous acid. The reduced nitrous acid causes an etching reaction with the silicon at a rapid rate. The reaction initiator according to some embodiments of the present disclosure is provided as a reducing compound to reduce the nitric acid to the nitrous acid.

Chemical Formula 3 represents a reduction reaction of the nitric acid by a reaction initiator RH and represents an example of a case in which an organic acid is used as the reaction initiator. In Chemical Formula 3, “R” is an organic acid having 2 to 30 carbon atoms except for hydrogen at an end.

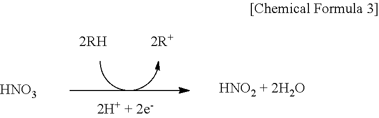

As in Chemical Formula 3, when the nitric acid is reduced to the nitrous acid, a reaction in operation b) of Chemical Formula 1 that is fast occurs more often. As a result, a reaction in which the silicon is oxidized by the nitrous acid is initiated, and at the same time, the etching reaction of the silicon by the nitrous acid is promoted. That is, as the etching composition contains the reaction initiator, the etching reaction starts without a time delay through a process of forming the nitrous acid, and a fast oxidation rate of the silicon may be implemented from an initial time. In some embodiments, when the initial reaction is initiated, chain etching reactions occur.

In some embodiments of the present disclosure, the etching composition may include about 10 wt % to 30 wt %, or any range therein, for example 15 wt %, 20 wt %, or 25 wt %, of the nitric acid based on the total weight of the etching composition. When the content of the nitric acid in the etching composition is too low, an etching reaction rate between the nitric acid and the silicon layer is decreased, and the reduction reaction to the nitrous acid by the reaction initiator is also decreased. As a result, an etching rate of the silicon layer may be too slow. In contrast, when the content of the nitric acid is too high, it is difficult to control the etching rate of the silicon layer to an appropriate level, and a morphology of an etched surface may become poor in a resulting object remaining after the silicon layer is etched.

In the etching composition according to some embodiments of the present disclosure, the hydrofluoric acid may serve to dissolve the silicon oxide formed by the nitric acid and the nitrous acid. A dissolution mechanism of the silicon oxide by the hydrofluoric acid may be expressed as b) in Chemical Formula 1.

The etching composition may include about 0.5 wt % to 15 wt %, or any range therein, for example, 5 wt % or 10 wt %, of the hydrofluoric acid based on the total weight of the etching composition. When the content of the hydrofluoric acid in the etching composition is too low, the etching rate of the silicon layer may become too slow, and when the content of the hydrofluoric acid is too high, the etching rate of the silicon layer may become too fast, which may result in an undercut phenomenon on an etching target surface or damage to a silicon lower layer.

In the etching composition according to some embodiments of the present disclosure, the phosphoric acid may serve to improve etching uniformity and make a profile of the etched surface good and may serve as a pH buffer that maintains a pH of the etching composition at an appropriate level. Further, the phosphoric acid may serve to maintain a viscosity of the etching composition at an appropriate level. The etching composition may include about 0.1 wt % to 30 wt %, or any range therein, for example, 1 wt %, 10 wt %, or 25 wt %, of the phosphoric acid based on the total weight of the etching composition. When the content of the phosphoric acid in the etching composition is too low, the profile of the etching target surface may become poor, and when the content of the phosphoric acid is too high, the etching rate may be decreased.

In the etching composition according to some embodiments of the present disclosure, the acetic acid may serve to suppress decomposition of the nitric acid, to stabilize the nitric acid, and thus to control the etching rate to an appropriate level. Further, the acetic acid may serve to improve wettability of the etching composition to the etching target surface so that the etching composition is well adsorbed to the etching target surface. Further, the acetic acid may serve as a pH buffer that maintains the pH of the etching composition at an appropriate level. The etching composition may include about 10 wt % to 50 wt %, or any range therein, for example, 15 wt %, 25 wt %, or 40 wt %, of the acetic acid based on the total weight of the etching composition. When the content of the acetic acid in the etching composition is too low or too high, it may be difficult to control the etching rate at an appropriate level.

In some embodiments of the present disclosure, the reaction initiator initiates a reaction between the nitrous acid and the silicon layer through the reduction of an acid compound, especially the nitric acid and promotes a reaction between the acid compound and the silicon layer. That is, the reaction initiator serves to accelerate the reduction reaction of the nitric acid, induce a chain reduction reaction of the nitric acid, and thus increase the etching rate of the silicon layer by the nitrous acid. The reaction initiator improves roughness of a surface of the silicon substrate when the silicon substrate is etched, by inducing a relatively uniform reaction within a short time regardless of a position on the surface of the silicon substrate. Here, in the case of the etching composition that does not use the reaction initiator, it is not easy to control the etching rate, and as a result, the morphology of the etched surface may become poor in the resulting object remaining after the silicon layer is etched. The poor morphology of the etched surface may mean an increase in the roughness of the silicon substrate, and as a result, may cause poor quality in a subsequent process on the silicon substrate. The reaction initiator according to some embodiments of the present disclosure serves to quickly and uniformly control the reaction initiation and the reaction rate of the silicon layer by promoting a reduction reaction of the nitric acid to the nitrous acid. Accordingly, the poor morphology of the etched surface of the silicon substrate may be significantly reduced.

In some embodiments of the present disclosure, the reaction initiator may be contained in 0.01 wt % to 3 wt %, or any range therein, for example, 0.1 wt %, 1 wt %, or 2 wt %, based on 100 wt % of the entire etching composition. When the reaction initiator is provided less than 0.01 wt %, the reduction reaction of the nitric acid does not occur sufficiently, and thus the silicon layer is not etched through the reduction reaction of the nitric acid or even when the etching is performed, the etching rate is slow. When the content of the reaction initiator is greater than 3 wt %, the etching reaction is quickly initiated, and the etching rate due to the etching reaction may be good, but etching selectivity according to the silicon layer is decreased. In particular, when there are silicon layers having different doping concentrations according to a doping concentration of impurities, the etching selectivity for two silicon layers is decreased.

The reaction initiator is mixed with the acid mixture to constitute the etching composition, and when the reaction initiator is mixed with the acid mixture, a mixing ratio (volume) may be 120:1 to 30:1, or any range therein, for example, 90:1 or 60:1.

The reaction initiator may include a reducing organic compound that may provide free electrons to the acid compound (e.g., a nitric acid compound) when the acid compound and the silicon layer react with each other.

In some embodiments of the present disclosure, the reducing organic compound may be provided as one capable of particularly providing electrons to the nitric acid that initiates the etching reaction, and may be, for example, a compound containing a carboxylic acid or an alcohol group.

In some embodiments of the present disclosure, a reducing sugar, an organic acid compound, a phenol compound, a thiol compound, a disulfide compound, a hydroxylamine compound, or any combinations thereof may be used as the reducing organic compound.

The organic acid compound may include an ascorbic acid, an ascorbyl palmitate, an ascorbyl glucoside, a sodium ascorbate, a potassium ascorbate, a calcium ascorbate, an erythorbic acid, a fumaric acid, a lactic acid, a citric acid, a malic acid, a butyric acid, a formic acid, a methanoic acid, an ethanoic acid, a propionic acid, a butanoic acid, a pentanoic acid, or any combinations thereof.

The reducing sugar may include glyceraldehyde, erythrose, ribose, xylose, arabinose, ribulose, glucose, fructose, mannose, galactose, maltose, lactose, cellobiose, dextrin, or any combinations thereof.

The phenol compound may include phenol, pyrocatechol, a caffeic acid, protocatechuic acid, a ferulic acid, hydroquinone, pyrogallol, a gallic acid, propyl gallate, or any combinations thereof.

The thiol compound may include cysteine, benzylmercaptan, 2-mercaptopyridine, benzothiazole-2-thiol, gamma-glutamylcysteine, 1-phenyl-5-mercaptotetrazole, glutathione, a mercaptopropionic acid, a mercaptoacetic acid, 2-mercaptobenzimidazole, 2-mercaptobenzothiazole, 2-mercapto-1methylimidazole, or any combinations thereof.

The disulfide compound may include cystine, dibenzyl disulfide, dipyridyl disulfide, dibenzothiazyl sulfide, thiamine disulfide, allithiamine, fursultiamine, diallyl disulfide, bis(2-methyl-3-furyl)disulfide, oxidized glutathione, or any combinations thereof.

In some embodiments of the present disclosure, the etching composition may further include a nitrogen compound in addition to the above components. The nitrogen compound includes at least one element selected from a fluorine atom “F,” a phosphorus atom “P,” and a carbon atom “C.”

The nitrogen compound may include an ammonium compound, urea, a urea derivative, an azole compound, or any combinations thereof.

The ammonium compound may include an ammonium fluoride, an ammonium bifluoride, an ammonium acetate, an ammonium sulfamate, an ammonium phosphate monobasic, an ammonium phosphate dibasic, an ammonium phosphate tribasic, an ammonium hydroxide, a tetramethylammonium hydroxide, a tetraethylammonium hydroxide, a tetrabutylammonium hydroxide, a tetramethylammonium fluoride, a tetrabutylammonium fluoride, or any combinations thereof.

The urea and/or the urea derivative may include urea, urea phosphate, urea nitrate, imidazolidinyl urea, phenylurea, N,N′-diphenylurea, hydroxyurea, urea peroxide, N,N-dimethylurea, or any combinations thereof.

The azole compound may include, as a 1,2,4-triazole compound, 1,2,4-triazole, 3-amino-1,2,4-triazole, 4-amino-1,2,4-triazole, 3,5-Diamino-1,2,4-triazole, 3,5-dimethyl-1,2,4-triazole, 3-amino-5-methyl-1,2,4-triazole, a 3-methyl-1,2,4-triazole-5-carboxylic acid, methyl 5-amino-1,2,4-triazole-3-carboxylate, or combinations thereof.

The hydroxylamine compound may include hydroxylamine, diethylhydroxylamine, phenylhydroxylamine, hydroxylamine sulfate, hydroxylamine phosphate, or combinations thereof.

In some embodiments of the present disclosure, the etching composition may include, as an acid mixture, 10 wt % to 30 wt % of the nitric acid, 0.5 wt % to 15 wt % of the hydrofluoric acid, 0.1 wt % to 30 wt % of the phosphoric acid, 10 wt % to 50 wt % of the acetic acid, 0.01 wt % to 3 wt % of the reaction initiator, and a remaining amount of water.

Further, the etching composition according to some embodiments of the present disclosure may contain a nitrogen compound. The nitrogen compound may serve to maintain the etching rate of the silicon layer by the etching composition and improve the etching selectivity at which a silicon layer having a doping concentration within a specific range among silicon layers having different doping concentrations may be selectively etched. While the desired silicon layer is etched using the etching composition, even when a silicon layer other than an etching target layer, for example, a silicon layer having a doping concentration that is different from a doping concentration of the etching target layer, is exposed together with the etching composition, the nitrogen compound may be selectively adsorbed on a surface of the silicon layer having the different doping concentration, and thus the silicon layer having the different doping concentration may be protected from etching, in some embodiments, about 0.5 wt % to 10 wt %, or any range therein, for example, 1 wt %, 4 wt %, or 7 wt %, of the nitrogen compound may be included. In the etching composition, when the content of the nitrogen compound is too low, it is difficult to maintain a constant etching selectivity of the etching composition, and when the content of the nitrogen compound is too high, the etching rate of the silicon layer to be etched may be too slow.

In some embodiments, in the etching composition according to an embodiment of the present disclosure, the content of the nitrogen compound may be smaller than the contents of the nitric acid, the hydrofluoric acid, the phosphoric acid, and the acetic acid. For example, in the etching composition according to some embodiments of the present disclosure, the content of the nitric acid may be at least twice the content of the nitrogen compound.

In some embodiments, the etching composition according to some embodiments of the present disclosure may be a composition for etching a single crystal silicon layer doped with a P-type impurity. In embodiments, the P-type impurity may be boron. In an example, the etching composition may be a composition for etching a silicon layer doped with boron at a concentration of about 1.0×10¹⁷ atoms/cm³ to about 8.0×10¹⁸ atoms/cm³, or any range therein, for example, 3.0×10¹⁷ atoms/cm³, 9.0×10¹⁷ atoms/cm³, or 3.0×10¹⁸ atoms/cm³. In another example, the etching composition may be a composition for etching the single crystal silicon layer doped with boron at a concentration of about 3.0×10¹⁷ atoms/cm³ to about 1.0×10¹⁸ atoms/cm³, or any range therein, for example, 5.0×10¹⁷ atoms/cm³, 7×10¹⁷ atoms/cm³, or 9.0×10¹⁷ atoms/cm³.

The etching composition according to some embodiments of the present disclosure may be used to treat a silicon substrate including the silicon layers having different impurity doping concentrations. The etching composition according to some embodiments of the present disclosure may be used to easily control a thickness of the silicon substrate by selectively etching a portion of the silicon substrate. The silicon substrate may be thinned by controlling the thickness of the silicon substrate.

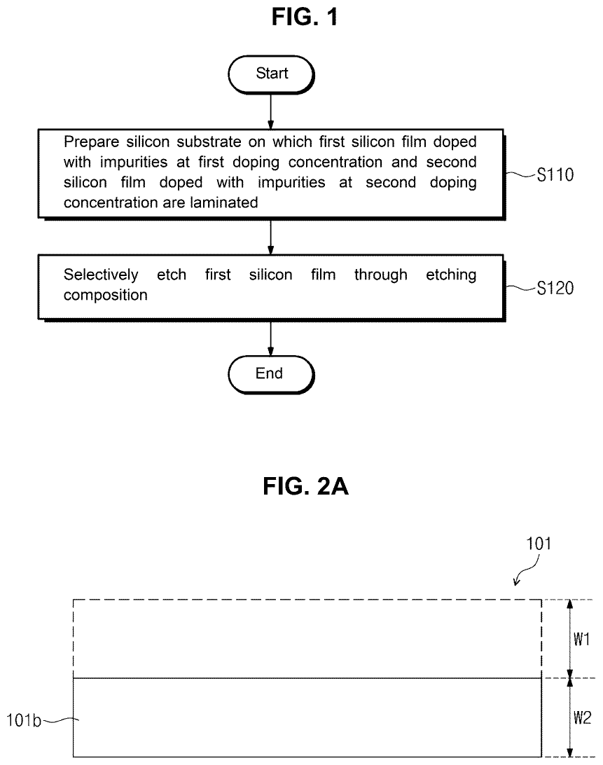

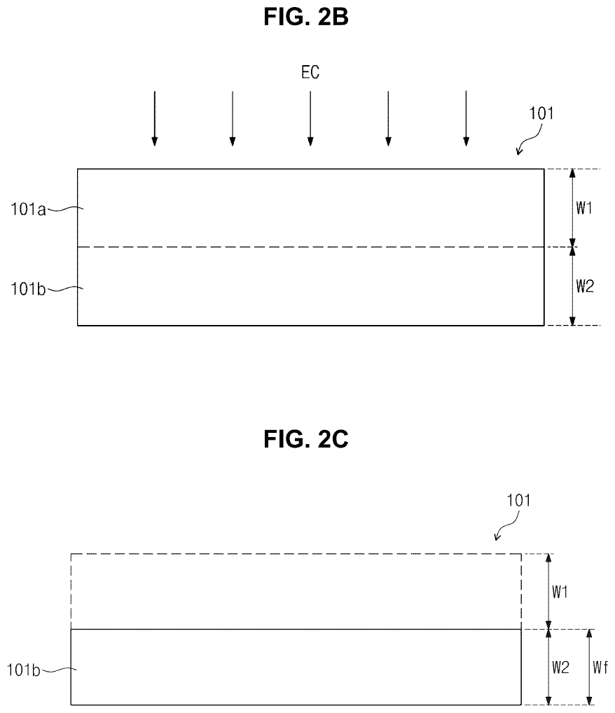

FIG. 1 is a flowchart illustrating a method of treating a silicon substrate using an etching composition according to an embodiment of the present disclosure, and FIGS. 2A to 2C are cross-sectional views sequentially describing a process of treating the silicon substrate using the etching composition according to some embodiments of the present disclosure.

Referring to FIGS. 1 and 2A to 2C, the method of treating the silicon substrate may include operation S110 of preparing a silicon substrate 101 in which a first silicon layer 101a doped with impurities at a first doping concentration and a second silicon layer 101b provided as an epitaxial layer and doped with impurities at a second doping concentration different from the first doping concentration are laminated and operation S120 of selectively etching the first silicon layer 101a among the first and second silicon layers 101a and 101b with the etching composition.

First, referring to FIGS. 1 and 2A, the silicon substrate 101 to be treated is prepared. Here, a process of treating the silicon substrate 101 may mean a process of reducing the silicon substrate 101 having a predetermined thickness to a desired thickness through the etching.

The silicon substrate 101 may include the first silicon layer 101a and the second silicon layer 101b, and the first silicon layer 101a and the second silicon layer 101b may be provided in a laminated form but are not separated.

The first silicon layer 101a and the second silicon layer 101b may be made of a single crystal silicon layer. In some embodiments of the present disclosure, the second silicon layer 101b may be made of a single crystal silicon layer epitaxially grown from a surface of the first silicon layer 101a. However, the crystal structures of the first silicon layer 101a and the second silicon layer 101b are not limited thereto and may be formed differently.

The first silicon layer 101a and the second silicon layer 101b may be layers that have characteristics that cause different degrees of etching when subsequently etched by the etching composition. For example, the first silicon layer 101a and the second silicon layer 101b may be previously doped with predetermined impurities, and the doping concentrations of the first silicon layer 101a and the second silicon layer 101b may be different from each other.

In some embodiments of the present disclosure, the first silicon layer 101a and the second silicon layer 101b may be doped with p-type impurities. The p-type impurities may be boron “B,” but the present disclosure is not limited thereto, and other impurities may be doped.

When a doping concentration of the impurities doped in the first silicon layer 101a is referred to as a first doping concentration, and a doping concentration of the impurities doped in the second silicon layer 101b is referred to as a second doping concentration, the first doping concentration may be greater than the second doping concentration. In some embodiments of the present disclosure, the first doping concentration in the first silicon layer 101a may be about 10 times to about 1.0×10⁵ times the second doping concentration in the second silicon layer 101b. However, the doping concentrations for the impurities in the two silicon layers are not limited thereto and may be changed depending on subsequent etching conditions, types of impurities, and the like. In some embodiments of the present disclosure, for example, the first silicon layer 101a may be doped with boron at a concentration of about 1.0×10¹⁷ atoms/cm³ to about 8.0×10¹⁸ atoms/cm³, and the second silicon layer 101b may be doped with boron at a concentration of about 5.0×10¹³ atoms/cm³ to about 1.0×10¹⁶ atoms/cm³.

In some embodiments of the present disclosure, in the silicon substrate 101, a thickness of the first silicon layer 101a and a thickness of second silicon layer 101b may be prepared in consideration of a thickness to be removed through the etching and the desired thickness of the silicon substrate 101 remaining after the etching. For example, the thickness of the second silicon layer 101b may correspond to the desired thickness after the thinning through the etching, and the thickness of the first silicon layer 101a may correspond to the thickness to be removed through the etching. That is, when the thickness of the first silicon layer 101a is referred to as a first thickness W1, and the thickness of the second silicon layer 101b is referred to as a second thickness W2, the thickness of the silicon substrate 101 before the etching process is performed may be a sum of the first thickness W1 and the second thickness W2, and the thickness of the silicon substrate 101 after the etching process may be the second thickness W2.

Referring to FIGS. 1 and 2B, an etching composition EC is provided on the silicon substrate 101 on which the first silicon layer 101a and the second silicon layer 101b are laminated. The etching composition EC is provided on the surface of the silicon substrate 101, for example, on the surface of the first silicon layer 101a.

The etching composition EC according to some embodiments of the present disclosure may selectively etch the first silicon layer 101a among the first silicon layer 101a and the second silicon layer 101b. In the etching composition EC, there is a difference between reactivities of the first silicon layer 101a and the second silicon layer 101b, and the reactivity of the first silicon layer 101a doped at the high concentration is greater than the reactivity of the second silicon layer 101b. Accordingly, the etching composition EC may react with silicon constituting the first silicon layer 101a on the surface of the first silicon layer 101a to etch the first silicon layer 101a. By etching the first silicon layer 101a, the first silicon layer 101a may be removed, and thus the surface of the second silicon layer 101b may be exposed.

In some embodiments of the present disclosure, a process of etching the first silicon layer 101a using the etching composition EC may be performed while the silicon substrate 101 is rotated using a spin manner in a single wafer type etching device that individually treats the silicon substrate 101. For example, to etch the first silicon layer 101a using the etching composition EC, while the etching composition EC is supplied onto the first silicon layer 101a using a nozzle (not illustrated), the silicon substrate 101 may be rotated at about 10 rpm to about 1000 rpm, or any range therein, for example, 100 rpm, 300 rpm, or 700 rpm. For example, as illustrated in FIG. 2B, the silicon substrate 101 may be rotated at about 300 rpm to about 700 rpm, or any range therein, for example, 400 rpm, 500 rpm, or 600 rpm, while the etching composition EC is supplied onto the first silicon layer 101a. The etching composition EC may be supplied onto the first silicon layer 101a at a flow rate of about 0.5 L/min to about 1.0 L/min, or any range therein, for example, 0.75 L/min or 0.9 L/min.

However, the technical spirit of the present disclosure is not limited to the above description. For example, the process of etching the first silicon layer 101a using the etching composition EC may be also performed using a batch-type etching device that simultaneously treats a plurality of silicon substrates 101.

The process of etching the first silicon layer 101a using the etching composition EC may be performed at room temperature. The term “room temperature” used therein is about 20° C. to about 28° C. and may be changed depending on the season.

Referring to FIGS. 1 and 2C, the first silicon layer 101a may be etched and removed by the etching composition EC, and the second silicon layer 101b remaining in the second thickness W2 may be cleaned and/or dried using various manners. In this case, a final thickness Wf of the silicon substrate 101 that is completely thinned is the second thickness W2.

The silicon substrate 101 on which only the second silicon layer 101b remains may be cleaned and/or dried in various manners. In some embodiments of the present disclosure, pure water may be used to clean the second silicon layer 101b, but the present disclosure is not limited thereto, and the second silicon layer 101b may be cleaned in various forms using various cleaning solutions. In some embodiments of the present disclosure, while the second silicon layer 101b is rotated at about 100 rpm to about 1,000 rpm, the second silicon layer 101b is cleaned by supplying the pure water onto the second silicon layer 101b at a flow rate of about 05. L/min to about 2.0 L/min, or any range therein, for example, 0.75 L/min, 1.0 L/min, or 1.5 L/min, for about 30 seconds to about two minutes, or any time range therein, for example 60 seconds or 90 seconds. The cleaned second silicon layer 101b may be dried while rotated at about 100 rpm to about 1,000 rpm, or any range therein, for example, 100 rpm, 300 rpm, or 700 rpm. The cleaning and drying process may be performed at room temperature.

The etching composition may be changed depending on a doping amount of the impurities, but when the first silicon layer 101a and the second silicon layer 101b have the doping concentrations presented in some embodiments of the present disclosure, for example, when the first silicon layer 101a is doped with boron at a concentration of about 1.0×10¹⁷ atoms/cm³ to about 8.0×10¹⁸ atoms/cm³, or any range therein, for example, 5.0×10¹⁷ atoms/cm³ or 1.0×10¹⁸ atoms/cm³, and the second silicon layer 101b is doped with boron at a concentration of about 5.0×10¹³ atoms/cm³ to about 1.0×10¹⁶ atoms/cm³, or any range therein, for example, 1.0×10¹⁴ atoms/cm³ or 1.0×10¹⁵ atoms/cm³, the first silicon layer 101a may be etched at a rate of about 0.1 μm/min or more, 0.5 μm/min or more, or 1.0 μm/min or more, and the second silicon layer 101b may be etched at a rate of 0.05 μm/min or less, 0.1 μm/min or less, or 0.2 μm/min or less. Further, a reaction initiation time may be within two minutes, within one minute, within 30 seconds, or within 15 seconds. In this way, the etching composition according to some embodiments of the present disclosure has excellent selectivity for the first silicon layer 101a and the second silicon layer 101b and also has a very short reaction initiation time as compared to an invention in which the reaction initiator is not used.

The silicon substrate 101 may be easily thinned through the above-described process.

According to some embodiments of the present disclosure, an additional process in addition to the etching using the etching composition may be further performed to achieve the thinning.

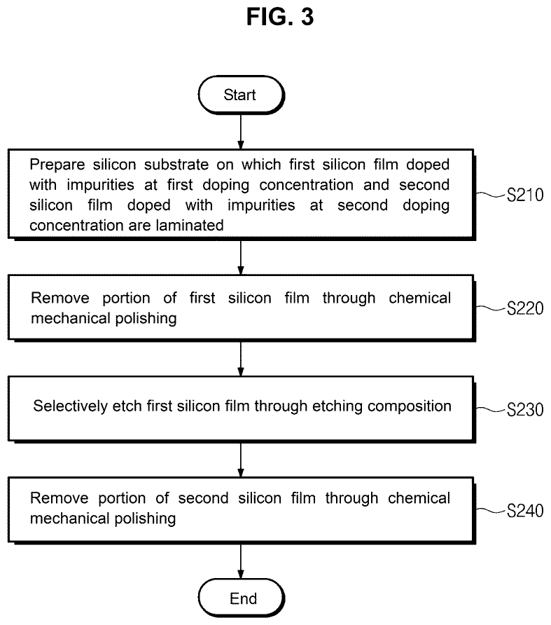

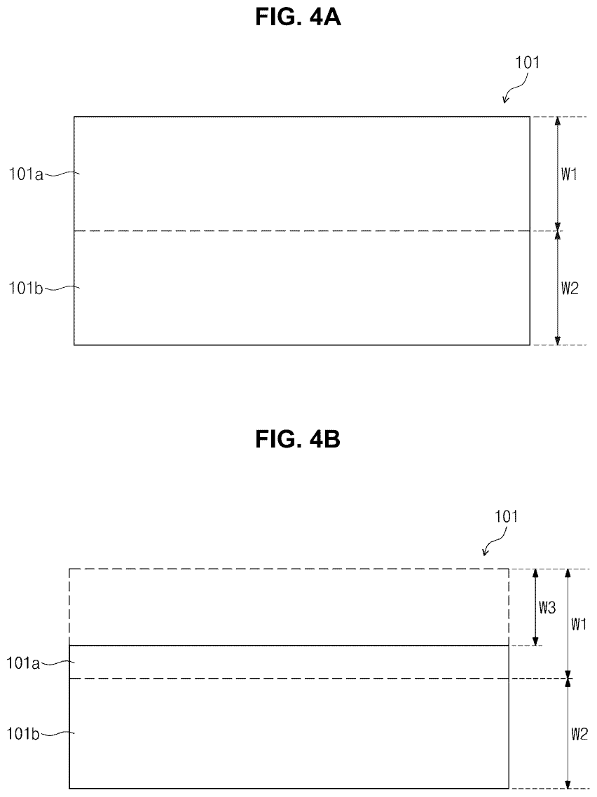

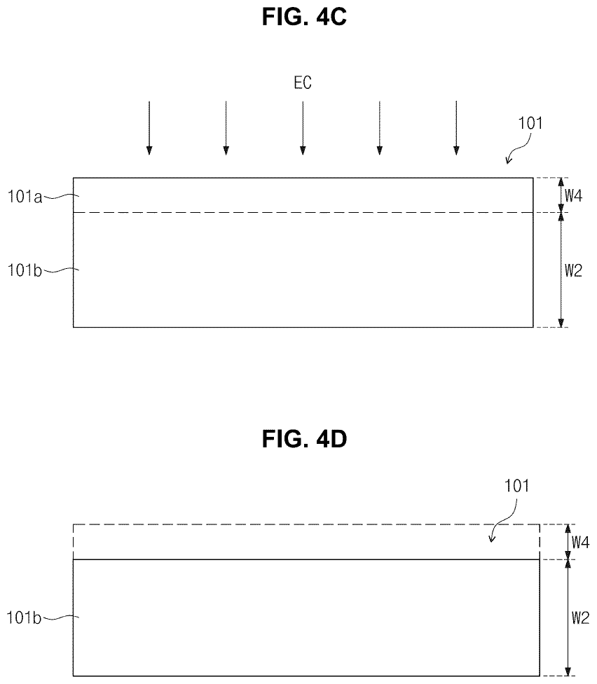

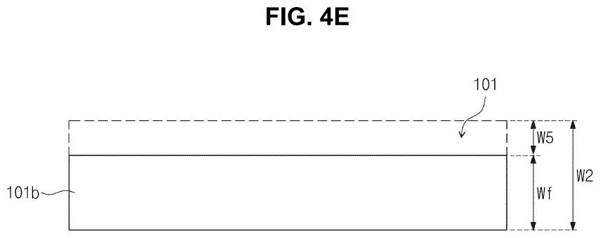

FIG. 3 is a flowchart illustrating the method of treating the silicon substrate according to some embodiments of the present disclosure, and FIGS. 4A to 4E are cross-sectional views sequentially describing the process of treating the silicon substrate.

Referring to FIGS. 3 and 4A to 4E, a method of treating the silicon substrate 101 may include operation S210 of preparing the silicon substrate 101 in which the first silicon layer 101a doped with impurities at the first doping concentration and the second silicon layer 101b provided as an epitaxial layer and doped with impurities at a second doping concentration different from the first doping concentration are laminated, operation S220 of removing a portion of the first silicon layer 101a through chemical mechanical polishing (CMP), operation S230 of selectively etching the portion of the first silicon layer 101a using the etching composition, and operation S240 of selectively removing a portion of the second silicon layer 101b through the CMP.

Referring to FIGS. 3 and 4A, the silicon substrate 101 to be treated is prepared.

The silicon substrate 101 to be treated is provided in a form including the first silicon layer 101a and the second silicon layer 101b. The first silicon layer 101a and the second silicon layer 101b may be provided in a laminated form but may be integrated without separation.

The first silicon layer 101a and the second silicon layer 101b may be made of a single crystal silicon layer. In some embodiments of the present disclosure, the second silicon layer 101b may be made of a single crystal silicon layer epitaxially grown from the surface of the first silicon layer 101a.

The first silicon layer 101a and the second silicon layer 101b may be layers that have characteristics that cause different degrees of etching when subsequently etched by the etching composition. For example, the first silicon layer 101a and the second silicon layer 101b may be doped with predetermined impurities, and the doping concentrations of the first silicon layer 101a and the second silicon layer 101b may be different from each other. When a doping concentration of the impurities doped in the first silicon layer 101a is referred to as a first doping concentration, and a doping concentration of the impurities doped in the second silicon layer 101b is referred to as a second doping concentration, the first doping concentration may be greater than the second doping concentration.

Referring to FIGS. 3 and 4B, the portion of the first silicon layer 101a of the silicon substrate 101 may be removed through the CMP. In the above-described embodiment, the entirety of the first silicon layer 101a is removed using the etching composition. However, the portion of the first silicon layer 101a is removed through the CMP, and thus a significant portion of the first silicon layer 101a may be easily removed without consuming the etching composition.

In some embodiments of the present disclosure, when the thickness of the first silicon layer 101a is referred to as the first thickness W1, and the thickness of the second silicon layer 101b is referred to as the second thickness W2, the portion of the first silicon layer 101a may be removed to a third thickness W3 that is smaller than the first thickness W1 through the CMP. The CMP may be performed in a direction from an upper surface of the first silicon layer 101a toward the second silicon layer 101b. In some embodiments of the present disclosure, only the portion of the first silicon layer 101a may be removed through the CMP, and the entire first silicon layer 101a may not be removed by the CMP. Accordingly, an upper surface of the second silicon layer 101b is still covered with the first silicon layer 101a and thus may not be exposed to the outside.

In some embodiments of the present disclosure, in an operation of removing the first silicon layer 101a by the third thickness W3, the above-described CMP may be used, but the present disclosure is not limited thereto, and a mechanical polishing process such as grinding without using chemicals may be also used. Alternatively, the operation of removing the first silicon layer 101a by the third thickness W3 may be performed using both the grinding and the CMP.

Referring to FIGS. 3 and 4C, the first silicon layer 101a remaining on the upper surface of the second silicon layer 101b after the CMP may be selectively etched using the etching composition EC. When a thickness of the first silicon layer 101a remaining on the upper surface of the second silicon layer 101b is referred to as a fourth thickness W4, a silicon layer having the fourth thickness W4 may be removed using the etching composition EC.

In the etching composition EC, there is a difference between the reactivities of the first silicon layer 101a and the second silicon layer 101b, and the reactivity of the first silicon layer 101a doped at the high concentration is greater than the reactivity of the second silicon layer 101b. Accordingly, the etching composition EC may react with silicon constituting the first silicon layer 101a on the surface of the first silicon layer 101a to easily etch the first silicon layer 101a. By etching the first silicon layer 101a, the first silicon layer 101a may be removed, and thus the surface of the second silicon layer 101b may be exposed.

In some embodiments of the present disclosure, the process of etching the first silicon layer 101a using the etching composition EC may be performed in a single wafer type or a batch type as described above.

Referring to FIGS. 3 and 4D, the silicon substrate 101 includes the second silicon layer 101b remaining after the etching using the etching composition. The process of treating the silicon substrate 101 may be terminated without an additional process for the second silicon layer 101b, and the second silicon layer 101b remaining with the second thickness W2 may be cleaned and/or dried in various manners. In this case, the final thickness Wf of the silicon substrate 101 that is completely thinned is the second thickness W2.

Referring to FIGS. 3 and 4E, when the silicon substrate 101 that is thinner than the second silicon layer 101b having the second thickness W2 is selectively required, the portion of the second silicon layer 101b may be further removed. When it is intended to remove the portion of the second silicon layer 101b, for example, to remove the second silicon layer 101b by a fifth thickness W5, additional CMP may be performed. The final thickness Wf of the silicon substrate 101 may be a thickness obtained by subtracting the fifth thickness W5 from the second thickness W2 of the second silicon layer 101b on which the CMP is performed.

The silicon substrate 101 may be more easily thinned through the above-described process of treating the silicon substrate 101.

The above-described process of treating the silicon substrate 101 may be applied to various methods of manufacturing integrated circuit (IC) devices. The IC device is generally obtained by forming an electronic circuit on a semiconductor material such as silicon and is implemented in a state in which a plurality of transistors, a semiconductor chip, a capacitor, a resistor, or the like are integrated into a die (or a semiconductor chip). This IC device may include the semiconductor chip, and thus when the thin silicon substrate 101 is used when the semiconductor chip is manufactured, the above-described process of treating the silicon substrate may be used. For example, the above-described process of treating the silicon substrate may be used when the semiconductor chip having a structure in which device parts are provided on both surfaces of the silicon substrate 101 and a through-via is formed to pass through the silicon substrate 101 is manufactured.

The semiconductor chip may be a logic semiconductor chip, a memory semiconductor chip, or any combinations thereof. For example, the logic semiconductor chip may be an application processor (AP), a micro-processor, a central processing unit (CPU), a controller, a graphic processor unit (GPU), a system-on-chip (SoC), an application specific integrated circuit (ASIC) or the like. Further, the memory semiconductor chip may be a volatile memory, such as a dynamic random access memory (DRAM) and a static random access memory (SRAM) or a non-volatile memory such as a phase-change random access memory (PRAM), a magneto-resistive random access memory (MRAM), a ferroelectric random access memory (FeRAM), or a resistive random access memory (RRAM).

Hereinafter, for convenience of description, the semiconductor chip that may be manufactured using the process of treating the silicon substrate is first described, and a method of manufacturing the same will be described below.

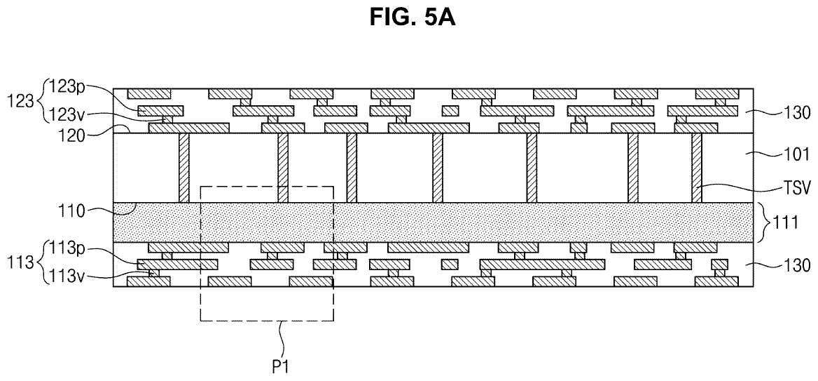

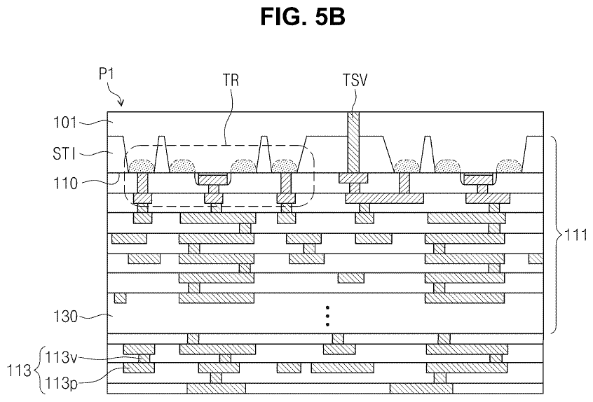

FIG. 5A is a cross-sectional view conceptually illustrating a semiconductor chip that may be manufactured using the process of treating the silicon substrate according to some embodiments of the present disclosure, and FIG. 5B is an enlarged cross-sectional view of a part corresponding to P1 in FIG. 5A.

Referring to FIGS. 5A and 5B, the semiconductor chip may include the silicon substrate 101 and a first device pattern and a second device pattern provided on both surfaces of the silicon substrate 101. The first device pattern may include a device part 111 and a first connection wiring line 113 connected to the device part 111. The second device pattern may include a second connection wiring line 123.

The silicon substrate 101 has a front surface 110 and a rear surface 120. In some embodiments, the front surface 110 and the rear surface 120, which are surfaces opposite to each other, may also be referred to as a first surface and a second surface. Here, the front surface 110 and the rear surface 120 are relative concepts, the front surface 110 means a surface, on which the device part 111 is formed, among both surfaces of the silicon substrate 101, and the rear surface 120 means a surface opposite to the front surface 110.

The silicon substrate 101 may be made of a single crystal silicon layer. The silicon substrate 101 may also be made of an epitaxially grown single crystal silicon layer. A portion of the silicon substrate 101 may be doped with predetermined impurities. In some embodiments, when the portion of the silicon substrate 101 is doped with impurities, the portion of the silicon substrate 101 may be doped with p-type impurities, and in this case, the p-type impurities may be boron.

The silicon substrate 101 may be provided with through-substrate vias (TSVs). In some embodiments, the TSVs penetrates the front surface 110 and the rear surface 120 of the silicon substrate 101. Ends of the TSVs are connected to components provided on the front surface of the silicon substrate 101, and the other ends thereof are connected to components provided on the rear surface of the silicon substrate 101. In some embodiments, the TSVs electrically connect the components provided on the front surface of the silicon substrate 101 and the components provided on the rear surface of the silicon substrate 101 to transmit power and various signals (e.g., a signal for controlling transistors or the like) from the components provided on the front surface of the silicon substrate 101 to the components provided on the rear surface of the silicon substrate 101 or vice versa.

In some embodiments of the present disclosure, the TSVs may electrically connect the first device pattern provided on the front surface of the silicon substrate 101 and the second device pattern provided on the rear surface of the silicon substrate 101. For example, the TSVs may electrically connect the device part 111 or the first connection wiring line 113 to the second connection wiring line provided on the rear surface of the silicon substrate 101.

In some embodiments, the TSVs may be provided in the form in which a recessed part is formed inside the silicon substrate 101 and an interior thereof is filled with a conductive material. The conductive material may be tungsten, cobalt, nickel, copper, silver, gold, tin, molybdenum, zinc, platinum, aluminum, doped polysilicon, or any combinations thereof.

in some embodiments, these TSVs may be implemented by thinning the silicon substrate 101. In some embodiments, when a thickness of the silicon substrate 101 is greater than a depth at which the TSVs may be formed, electrical connection between the front surface 110 and the rear surface 120 of the silicon substrate 101 through the TSVs is impossible. Accordingly, in some embodiments, when it is intended to manufacture the semiconductor chip having the TSVs, the silicon substrate 101 needs to be thinned, and the silicon substrate 101 may be thinned by the method of treating the silicon substrate 101 using the etching composition. This will be described below.

The device part 111 may be an area that includes various ICs inside the silicon substrate 101. The device part 111 may be provided on the front surface 110 of the silicon substrate 101 and include various micro-electronic devices. The micro-electronic device may be, for example, a complementary metal-insulator-semiconductor transistor (CMOS) transistor, a metal-oxide-semiconductor field effect transistor (MOSFET), a system large scale integration (LSI), an image sensor such as a CMOS imaging sensor (CIS), a micro-electro-mechanical system (MEMS), various active devices, various passive devices, or any combinations of the active device and the passive device. For convenience of description, as an example, FIG. 5B illustrates transistors TR as a portion of the device part 111. The silicon substrate 101 in which the transistors TR are provided may be provided with a shallow device isolation layer STI that separates the adjacent transistors TR.

In some embodiments, the first connection wiring line 113 is provided on the device part 111. The first connection wiring line 113 may be provided as a first conductive wiring line structure including at least one layer electrically connected to the device part 111. The first conductive wiring line structure may include an interlayer insulating layer 130 provided on the device part 111, a first conductive pattern 113p provided on the interlayer insulating layer 130, and a first conductive via 113v penetrating the interlayer insulating layer 130. In some embodiments, the first conductive pattern 113p is adapted to transmit an electrical signal and power in a lateral direction, and the first conductive via 113v is adapted to transmit an electrical signal and power in a vertical direction. The first conductive pattern 113p may be provided as a plurality of first conductive patterns 113p, and the first conductive via 113v may be provided as a plurality of first conductive vias 113v. Therefore, the device part 111 and the first connection wiring lines 113 may be electrically connected to each other or the first connection wiring lines 113 may be electrically connected to each other in various forms.

The interlayer insulating layer 130 may include an appropriate dielectric material such as a silicon oxide, a silicon nitride, a silicon oxy nitride, a silicon carbide, or any combinations thereof. Further, the interlayer insulating layer 130 may include a dielectric material such as an undoped silicate glass (USG), a phospho-silicate glass (PSG), a boro-silicate glass (BSG), and a boron-doped phospho-silicate glass (BPSG).

Each of the first conductive pattern 113p and the first conductive via 113v may be formed of various conductive materials, for example, tungsten, cobalt, nickel, copper, silver, gold, tin, molybdenum, zinc, platinum, aluminum, or any combinations thereof.

The second device pattern is provided on the rear surface 120 of the silicon substrate 101. In the present embodiment, it is illustrated as an example that the second connection wiring line 123 is formed on the second silicon layer 101b, but the present disclosure is not limited thereto, and it is obvious that various devices in addition to the second connection wiring line 123 may be further formed on the second silicon layer 101b.

The second connection wiring line 123 may be connected to the TSVs and may be provided as a second conductive wiring line structure. The second conductive wiring line structure includes at least one layer. The second conductive wiring line structure may include the interlayer insulating layer 130 provided on the device part 111, a second conductive pattern 123p provided on the interlayer insulating layer 130, and a second conductive via 123v penetrating the interlayer insulating layer 130. The second conductive pattern 123p is adapted to transmit an electrical signal and power in the lateral direction, and the second conductive via 123v is adapted to transmit an electrical signal and power in the vertical direction. The second conductive pattern 123p may be provided as a plurality of second conductive patterns 123p, and the second conductive via 123v may be provided as a plurality of second conductive vias 113v. Therefore, the device part 111 and the second connection wiring lines 123 may be electrically connected to each other or the second connection wiring lines 123 may be electrically connected to each other in various forms.

The interlayer insulating layer 130 of the second conductive wiring line structure may include an appropriate dielectric material such as a silicon oxide, a silicon nitride, a silicon oxy nitride, a silicon carbide, or any combinations thereof, as described above. Further, the interlayer insulating layer 130 may include a dielectric material such as an undoped silicate glass (USG), a phospho-silicate glass (PSG), a boro-silicate glass (BSG), and a boron-doped phospho-silicate glass (BPSG).

Each of the second conductive pattern 123p and the second conductive via 123v may be formed of various conductive materials, for example, tungsten, cobalt, nickel, copper, silver, gold, tin, molybdenum, zinc, platinum, aluminum, or any combinations thereof.

In some embodiments of the present disclosure, at least a portion of the second connection wiring line 123 may constitute a power delivery network, PDN. The PDN may distribute and transmit power to the device part 111. In other words, the PDN may be at least a portion of the second connection wiring line 123 and include the second conductive pattern 123p and the second conductive via 123v, and the second conductive pattern 123p may be a continuous or discontinuous pattern.

In some embodiments of the present disclosure, the silicon substrate 101 is provided with the TSV.

The TSVs penetrate the front surface 110 and the rear surface 120 of the silicon substrate 101. Ends of the TSVs may be connected to the device part 111 or the first connection wiring line 113, and the other ends thereof may be connected to the second connection wiring line 123. The other ends of at least some of the TSVs are electrically connected to the PDN of the second connection wiring line 123.

The TSVs may be provided in the form in which the recessed part is formed inside the silicon substrate 101 and the interior thereof is filled with a conductive material. The conductive material may be tungsten, cobalt, nickel, copper, silver, gold, tin, molybdenum, zinc, platinum, aluminum, doped polysilicon, or any combinations thereof.

Although not illustrated, a first pad part and a second pad part connected to an external component through the first connection wiring line 113 and the second connection wiring line 123 may be provided on the first connection wiring line 113 and the second connection wiring line 123. Further, although not illustrated, various types of connectors for electrical connection with the external component may be provided on the first pad part and the second pad part. The connector is provided for the electrical connection with the external component and may include, for example, a micro bump, a metal pillar, a ball grid array (BGA) solder ball, a solder ball and a cored solder ball having various sizes, or any combinations thereof.

In some embodiments of the present disclosure, the second pad part may be provided on the second connection wiring line 123. At least a portion of the second pad part may be connected to the PDN to apply a power voltage to the device part 111 through the PDN. In some embodiments of the present disclosure, the entire second connection wiring line 123 may be used to form the PDN, but the present disclosure is not limited thereto, and a portion of the second connection wiring line 123 may be connected to a wiring line that transmits a signal that does not correspond to the PDN.

The IC device having the above structure does not need to form a power wiring line (e.g., the PDN) for supplying power to the device part 111 on the front surface of the silicon substrate 101. That is, the power wiring line is formed on the rear surface of the silicon substrate 101, and thus a space on the front surface, in which the power wiring line is positioned, may be secured as an additional extra space.

The IC device generally has a multi-layer wiring line layer formed on the same surface as the silicon substrate on which the device part is formed and supplies power to the device part. Accordingly, the PDN is formed on the same surface as the silicon substrate on which the device part is formed. However, as a degree of integration of the IC device is increased, a space in which devices such as a transistor are integrated is insufficient due to the PDN that occupies a large area. In some embodiments of the present disclosure, the PDN is formed on the rear surface of the silicon substrate, and thus this problem may be solved. A position of the PDN is changed from the front surface of the silicon substrate, in which the device part is formed, to the rear surface, and thus a degree of freedom in arrangement of other signal wiring lines and the device parts provided on the front surface of the silicon substrate is improved. According to some embodiments of the present disclosure, the degree of freedom in the arrangement of the other signal wiring lines provided on the front surface of the silicon substrate is increased, and thus paths for the signal wiring lines may be shortened or widened, and a resistance-capacitance (RC) delay phenomenon is reduced.

In some embodiments of the present disclosure, the IC devices are illustratively provided as an embodiment in which the method of treating the silicon substrate is adopted, although embodiments of the present disclosure are not limited thereto. When the IC device is manufactured, it is necessary to increase or decrease the thickness of the silicon substrate for various purposes, and in this case, the thickness of the silicon substrate may be controlled using the etching composition according to some embodiments of the present disclosure. In particular, in some embodiments of the present disclosure, a state in which the process of treating the silicon substrate is used when the IC device in which the TSVs electrically connecting the components on the front surface and the rear surface of the silicon substrate are formed is manufactured is illustrated as an example, but the present disclosure is not limited thereto. For example, the silicon substrate may be provided with other components that penetrate the front surface and the rear surface of the silicon substrate depending on the type of IC device. Even when the other components are provided, when the silicon substrate is treated to control the thickness of the silicon substrate, this case may be included in some embodiments of the present disclosure. For example, when the IC device is an image sensor including a plurality of pixels, the silicon substrate may be provided with a deep trench isolation (DTI) layer that partitions the pixels and penetrates the front surface and the rear surface of the silicon substrate. In addition, according to some embodiments, the silicon substrate may not be provided with the TSVs, the DTI layer or the like.

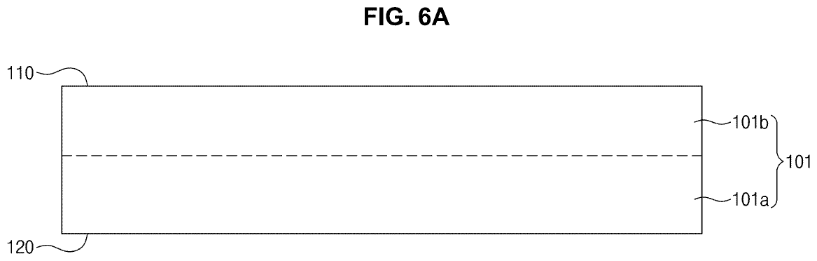

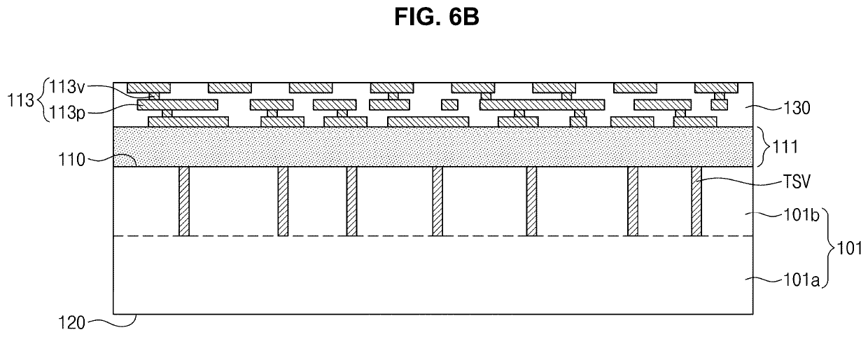

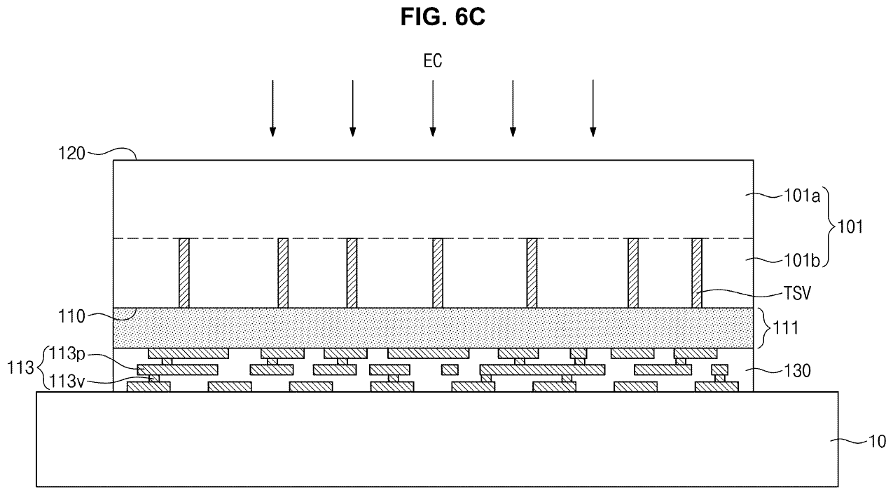

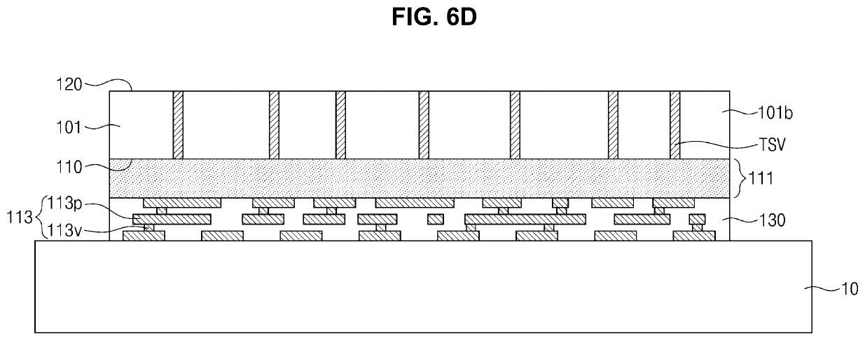

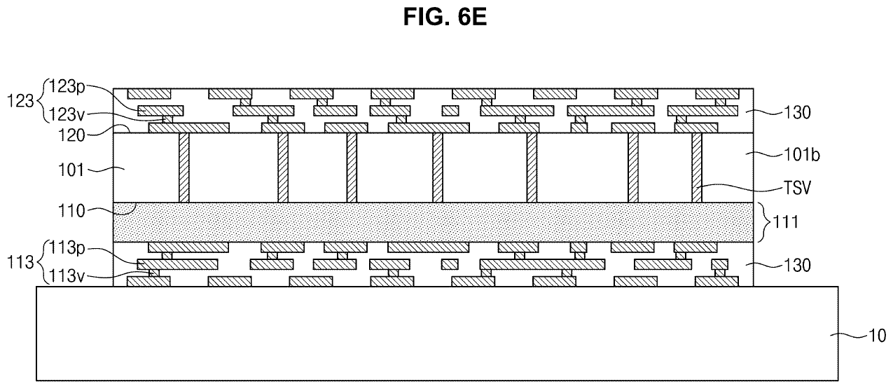

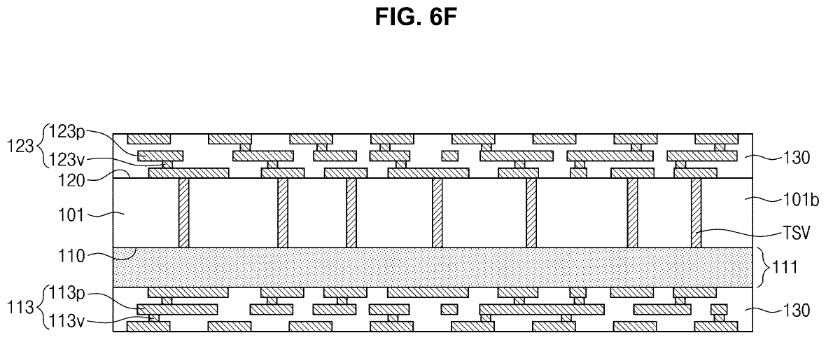

FIGS. 6A to 6E are illustrative cross-sectional views sequentially illustrating a method of manufacturing the IC device according to some embodiments of the present disclosure.

Referring to FIG. 6A, the silicon substrate 101 for manufacturing the IC device is prepared.

The silicon substrate 101 is provided in a form including the first silicon layer 101a and the second silicon layer 101b. The first silicon layer 101a and the second silicon layer 101b may be provided in a laminated form but may be integrated without separation. The first silicon layer 101a and the second silicon layer 101b may be made of a single crystal silicon layer. In some embodiments of the present disclosure, the second silicon layer 101b may be made of a single crystal silicon layer epitaxially grown from the surface of the first silicon layer 101a.

In some embodiments of the present disclosure, the silicon substrate 101 has the first surface 110 and the second surface 120. In some embodiments, when the first silicon layer 101a and the second silicon layer 101b are laminated from below to above, a surface of the second silicon layer 101b, exposed to the outside, that is, an upper surface thereof, may be referred to as the first surface (or the front surface), and a surface of the first silicon layer 101a, exposed to the outside, that is, a lower surface thereof, may be referred to as the second surface (or the rear surface).

The first silicon layer 101a and the second silicon layer 101b may be layers treated to have different etching characteristics when etched with the etching composition. For example, the first silicon layer 101a and the second silicon layer 101b may be previously doped with predetermined impurities, and the doping concentrations of the first silicon layer 101a and the second silicon layer 101b may be different from each other. In some embodiments of the present disclosure, the doping concentration of the first silicon layer 101a may be greater than the doping concentration of the second silicon layer 101b. For example, the first silicon layer 101a may be made of a single crystal silicon layer doped with boron at a concentration of about 1.0×10¹⁷ atoms/cm³ to about 8.0×10¹⁸ atoms/cm³, or any range therein, for example, 9.0×10¹⁷ atoms/cm³ or 3.0×10¹⁸ atoms/cm³, and the second silicon layer 101b may be made of a single crystal silicon layer doped with boron at a concentration of about 5.0×10¹³ atoms/cm³ to about 1.0×10¹⁶ atoms/cm³, or any range therein, for example, 1.0×10¹⁴ atoms/cm³ or 1.0×10¹⁵ atoms/cm³. For example, the first silicon layer 101a may be made of a single crystal silicon layer doped with boron at a concentration of about 3.0×10¹⁷ atoms/cm³ to about 6.0×10¹⁸ atoms/cm³, or any range therein for example, 9.0×10¹⁷ atoms/cm³ or 3.0×10¹⁸ atoms/cm³, and the second silicon layer 101b may be made of a single crystal silicon layer doped with boron at a concentration of about 8.0×10¹³ atoms/cm³ to about 5.0×10¹⁵ atoms/cm³, or any range therein for example, 1.0×10¹⁴ atoms/cm³ or 1.0×10¹⁵ atoms/cm³. In some embodiments, the doping concentration in the first silicon layer 101a may be about 10 times to about 1.0×10⁵ times the doping concentration in the second silicon layer 101b, or any range therein, for example, about 1000 times or 10,000 times. In some embodiments, the thickness of the first silicon layer 101a may be greater than the thickness of the second silicon layer 101b.

Referring to FIG. 6B, the device part 111 and the first connection wiring line 113 may be formed on the front surface of the silicon substrate 101. At least a portion of the first connection wiring line 113 is connected to the device part 111. The device part 111 and the first connection wiring line 113 may be referred to as the first device pattern.

The first device pattern may be formed on the front surface of the silicon substrate 101 through various processes including photolithography.

In some embodiments of the present disclosure, the t TSVs may be formed in addition to forming the first device pattern, that is, the device part 111 and the first connection wiring line 113. That is, a process of forming the t TSVs that penetrate at least a portion of the silicon substrate 101 may be included in the process of forming the first device pattern. For example, the TSVs may be formed before the device part 111 and the first connection wiring line 113 are formed or may be simultaneously formed using at least a portion of the process of forming the device part 111 and the first connection wiring line 113.

The TSVs formed in the silicon substrate 101 may be formed at a predetermined depth from the front surface of the silicon substrate 101. A depth of the TSVs may be formed to have a length longer than a thickness to be etched and removed by the silicon substrate 101 later in consideration of the thickness to be etched and removed. For example, when the silicon substrate 101 is treated and the first silicon layer 101a is removed, the depth of the t TSVs may be equal to or greater than a depth of the second silicon layer 101b so that the TSVs of the second silicon layer 101b penetrate both surfaces of the second silicon layer 101b. Alternatively, when the silicon substrate 101 is treated and a portion of the second silicon layer 101b in addition to the first silicon layer 101a is removed, the depth of the TSVs may be formed to be smaller than the depth of the second silicon layer 101b.

Referring to FIGS. 6C, the etching composition EC is provided on a portion of the silicon substrate 101 on which the first silicon layer 101a and the second silicon layer 101b are laminated. The etching composition EC is provided on the second surface, that is, the rear surface, of the first silicon layer 101a. Here, to selectively etch the silicon substrate 101, in some embodiments, a separate support substrate 10 may be prepared, and then the silicon substrate 101 on which the first device pattern is formed may be disposed upside down on the support substrate 10.

The etching composition EC according to some embodiments of the present disclosure may selectively etch the first silicon layer 101a among the first silicon layer 101a and the second silicon layer 101b. In the etching composition, there is a difference between the reactivities of the first silicon layer 101a and the second silicon layer 101b, and the reactivity of the first silicon layer 101a doped at the high concentration is greater than the reactivity of the second silicon layer 101b. Accordingly, the etching composition may react with the silicon constituting the first silicon layer 101a on the surface of the first silicon layer 101a to etch the first silicon layer 101a. By etching the first silicon layer 101a, the first silicon layer 101a may be removed, and thus the surface of the second silicon layer 101b may be exposed.

In some embodiments of the present disclosure, the process of etching the first silicon layer 101a using the etching composition EC may be performed while the silicon substrate 101 is rotated using the spin manner in the single wafer type etching device that individually treats the silicon substrate 101. However, the technical spirit of the present disclosure is not limited to the above description. For example, the process of etching the first silicon layer 101a using the etching composition may be also performed using the batch-type etching device that simultaneously treats the plurality of silicon substrates 101.

Referring to FIG. 6D, the first silicon layer 101a is etched and removed, and thus the second silicon layer 101b may be exposed to the outside. In this case, first ends of the TSVs may also be exposed to the outside.

The silicon substrate 101 on which the first silicon layer 101a is etched may be cleaned and/or dried. In some embodiments of the present disclosure, the silicon substrate 101 may be cleaned with pure water. However, the present disclosure is not limited thereto, and the silicon substrate 101 may be cleaned in various forms using various cleaning solutions. The cleaned silicon substrate 101 may be dried.

Referring to FIG. 6E, the second connection wiring line 123 corresponding to the second device pattern may be formed on the second silicon layer 101b, that is, on the rear surface of the silicon substrate 101. In the present embodiment, it is illustrated as an example that the second connection wiring line 123 is formed on the second silicon layer 101b, but the present disclosure is not limited thereto, and it is obvious that various devices in addition to the wiring lines may be further formed on the second silicon layer 101b.

The first device pattern and the second device pattern are provided on the front surface and the rear surface of the silicon substrate 101 made of the second silicon layer 101b, the TSVs are provided between the first device pattern and the second device pattern, and thus the first device pattern and the second device pattern may be electrically connected to each other.

Referring to FIG. 6F, the IC device may be completed by removing the support substrate 10.

Although not illustrated, in some embodiments of the present disclosure, a structure for connection to other components may be added to the IC device in the form of a connector or the like formed on at least one surface, and the IC device may be easily manufactured through the above-described process.

FIGS. 6A to 6F illustrate an embodiment in which the first silicon layer is removed using the etching composition when the IC device is manufactured, but the present disclosure is not limited thereto, and it is obvious that an additional CMP process or the like may be optionally added, which is similar to the description of FIGS. 4A to 4E.

In some embodiments of the present disclosure, the method of manufacturing the semiconductor chip including the thin silicon substrate has been described, but the present disclosure is not limited thereto. Even in electronic devices other than the semiconductor chip, in a manufacturing process that requires the thinning of the silicon substrate, the silicon substrate may be treated using the etching composition without departing from the concept of the present disclosure.

### Working Examples

To identify etching efficiency of the silicon substrate using an etching composition according to a comparative example and an etching composition according to an example, etching was performed under different conditions.

Table 1 below represents a composition ratio and an evaluation result of the etching composition in a reaction of etching the silicon substrate using the etching composition according to some embodiments of the present disclosure.

The silicon substrate including the first silicon layer made of a single crystal silicon wafer and the second silicon layer epitaxially grown from the single crystal wafer was prepared. In the etching process, the silicon substrate was immersed and stirred in the etching composition at 25° C. for five minutes.

A reaction initiation time point of the etching process was measured by identifying a time point at which color of a sample of the silicon substrate used in an experiment was changed. For the reaction initiation time point, when the etching reaction was initiated in less than five seconds, “⊚” was marked, when the etching reaction was initiated in greater than or equal to five seconds and smaller than 15 seconds, “∘” was marked, and when the etching reaction was initiated in greater than or equal to 15 seconds and smaller than 25 seconds, “x” was marked.

An etch rate of the first silicon layer of the silicon substrate was identified by measuring the total thickness of the silicon substrate through a micrometer before the etching reaction and after the etching was completed.

When the etch rate of the first silicon layer was greater than 4 μm/min, “⊚” was marked, when the etch rate of the first silicon layer was greater than or equal to 1 μm/min and smaller than 4 μm/min, “∘” was marked, when the etch rate of the first silicon layer was greater than or equal to 0.7 μm/min and smaller than 1 μm/min, “Δ” was marked, and when the etch rate of the first silicon layer was greater than or equal to of 0 μm/min and smaller than to 0.7 μm/min, “x″ was marked.

An etch rate of the second silicon layer of the silicon substrate was identified by measuring the total thickness of the silicon substrate through a FE-SEM before the etching reaction and after the etching was completed.

When the etch rate of the second silicon layer was greater than or equal to of 0 μm/min and smaller than 0.15 μm/min, “⊚” was marked, when the etch rate of the second silicon layer was greater than or equal to 0.15 μm/min and smaller than 0.2 μm/min, “∘” was marked, when the etch rate of the second silicon layer was greater than or equal to 0.2 μm/min and smaller than 0.3 μm/min, “Δ” was marked, and when the etch rate of the second silicon layer was greater than 0.3 μm/min, “x” was marked.

TABLE 1

| | | | | | | | Evaluation result | | |
|---|---|---|---|---|---|---|---|---|---|
| | wt % | | | | | | | First | Second |
| | Hydro- | | Phos- | | | | | silicon | silicon |
| | fluoric | Nitric | phoric | Acetic | Nitrogen | Reaction | Reaction | layer | layer |
| | acid | acid | acid | acid | compound | initiator | initiation | etch rate | etch rate |
| Embodi- | 1.5 | 25.5 | 18 | 24 | Ammonium | Fructose | ⊚ | ◯ | ⊚ |
| ment 1 | | | | | fluoride | 2 | | | |
| | | | | | 0.1 | | | | |
| Embodi- | 1.5 | 25.5 | 17.5 | 24.5 | Ammonium | Glucose | ◯ | ◯ | ⊚ |
| ment 2 | | | | | fluoride | 0.5 | | | |
| | | | | | 0.5 | | | | |
| Embodi- | 1.5 | 25.5 | 17.5 | 24.5 | Ammonium | Ascorbic | ⊚ | ◯ | ⊚ |
| ment 3 | | | | | fluoride | acid | | | |
| | | | | | 0.5 | 0.3 | | | |
| Embodi- | 1.5 | 25.5 | 17.5 | 24.5 | Ammonium | Ascorbic | ⊚ | ◯ | ◯ |
| ment 4 | | | | | fluoride | acid | | | |
| | | | | | 0.5 | 1 | | | |
| Embodi- | 3 | 30 | 9 | 26 | Ammonium | Cysteine | ◯ | ◯ | ⊚ |
| ment 5 | | | | | bifluoride | 2 | | | |
| | | | | | 0.5 | | | | |
| Embodi- | 3 | 30 | 9 | 26 | Ammonium | Cystine | ◯ | ◯ | ⊚ |
| ment 6 | | | | | bifluoride | 2 | | | |
| | | | | | 0.5 | | | | |
| Embodi- | 5.5 | 23.5 | 9.5 | 29 | Ammonium | Hydroquinone | ⊚ | ⊚ | ⊚ |
| ment 7 | | | | | bifluoride | 0.5 | | | |
| | | | | | 0.5 | | | | |
| Embodi- | 7.5 | 25.5 | 0.5 | 33 | Ammonium | Diethylhy- | ⊚ | ⊚ | ◯ |
| ment 8 | | | | | bifluoride | droxylamine | | | |
| | | | | | 0.5 | 0.05 | | | |
| Embodi- | 6.5 | 13.6 | 27.7 | 15.9 | Ammonium | Hydroxyl- | ◯ | ⊚ | ⊚ |
| ment 9 | | | | | fluoride | amine | | | |
| | | | | | 2.1 | 0.05 | | | |
| Embodi- | 4.3 | 18.8 | 21.1 | 20 | Ammonium | Diethylhy- | ⊚ | ◯ | ⊚ |
| ment | | | | | fluoride | droxylamine | | | |
| 10 | | | | | 2.6 | 0.05 | | | |
| Embodi- | 4.3 | 18.8 | 21.1 | 20 | Ammonium | Hydroxyl- | ⊚ | ⊚ | ⊚ |
| ment | | | | | bifluoride | amine | | | |
| 11 | | | | | 1.5 | 0.05 | | | |
| Embodi- | 13.3 | 11.1 | 10.8 | 39.4 | Ammonium | Hydroxyl- | ⊚ | ⊚ | ◯ |
| ment | | | | | fluoride | amine | | | |
| 12 | | | | | 2.6 | 0.05 | | | |
| Embodi- | 13.3 | 11.1 | 10.8 | 39.4 | Ammonium | Hydroxyl- | ⊚ | ◯ | ⊚ |
| ment | | | | | Acetate | amine | | | |
| 13 | | | | | 5 | 0.1 | | | |
| Embodi- | 13.3 | 11.1 | 10.8 | 39.4 | Ammonium | Hydroxyl- | ⊚ | ◯ | ⊚ |
| ment | | | | | phosphate | amine | | | |
| 14 | | | | | monobasic | 0.1 | | | |
| | | | | | 5 | | | | |
| Embodi- | 13.3 | 11.1 | 10.8 | 39.4 | Tetramethyl- | Hydroxyl- | ⊚ | ⊚ | ◯ |
| ment | | | | | ammonium | amine | | | |
| 15 | | | | | fluoride | 0.1 | | | |
| | | | | | 4.2 | | | | |
| Embodi- | 13.3 | 11.1 | 10.8 | 39.4 | Tetrabutyl- | Hydroxyl- | ⊚ | ⊚ | ◯ |
| ment | | | | | ammonium | amine | | | |
| 16 | | | | | fluoride | 0.1 | | | |
| | | | | | 5 | | | | |
| Embodi- | 13.3 | 11.1 | 10.8 | 39.4 | Tetramethyl- | Hydroxyl- | ⊚ | ⊚ | ⊚ |
| ment | | | | | ammonium | amine | | | |
| 17 | | | | | hydroxide | 0.1 | | | |
| | | | | | 2 | | | | |
| Embodi- | 13.3 | 11.1 | 10.8 | 39.4 | Urea | Hydroxyl- | ⊚ | ⊚ | ⊚ |
| ment | | | | | 2.8 | amine | | | |
| 18 | | | | | | 0.2 | | | |
| Embodi- | 13.3 | 11.1 | 10.8 | 39.4 | Urea | Hydroxyl- | ⊚ | ⊚ | ⊚ |
| ment | | | | | phosphate | amine | | | |
| 19 | | | | | 3 | 0.2 | | | |
| Embodi- | 13.3 | 11.1 | 10.8 | 39.4 | Urea nitrate | Hydroxyl- | ⊚ | ⊚ | ⊚ |
| ment | | | | | 3 | amine | | | |
| 20 | | | | | | 0.2 | | | |
| Embodi- | 13.3 | 11.1 | 10.8 | 39.4 | Phenylurea | Hydroxyl- | ⊚ | ⊚ | ◯ |
| ment | | | | | 0.9 | amine | | | |
| 21 | | | | | | 0.05 | | | |
| Embodi- | 13.3 | 11.1 | 10.8 | 39.4 | 4-amino- | Hydroxyl- | ⊚ | ⊚ | ◯ |
| ment | | | | | 1,2,4- | amine | | | |
| 22 | | | | | triazole | 0.05 | | | |
| | | | | | 0.7 | | | | |
| Embodi- | 13.3 | 11.1 | 10.8 | 39.4 | 3-Amino-5- | Hydroxyl- | ⊚ | ⊚ | ◯ |
| ment | | | | | methyl- | amine | | | |
| 23 | | | | | 1,2,4- | 0.05 | | | |
| | | | | | triazole | | | | |
| | | | | | 0.7 | | | | |

In the case of embodiment 1 and embodiment 2, the reaction initiation, the first silicon layer etch rate, and the second silicon layer etch rate were all satisfied through a mixed composition including a hydrofluoric acid, a nitric acid, a phosphoric acid, an acetic acid, an ammonium salt compound, and a monosaccharide.

In the case of embodiment 3 and embodiment 4, the reaction initiation, the first silicon layer etch rate, and the second silicon layer etch rate were all satisfied through a mixed composition including a hydrofluoric acid, a nitric acid, a phosphoric acid, an acetic acid, an ammonium salt compound, and an ascorbic acid.

In the case of embodiment 5, the reaction initiation, the first silicon layer etch rate, and the second silicon layer etch rate were all satisfied through a mixed composition including a hydrofluoric acid, a nitric acid, a phosphoric acid, an acetic acid, an ammonium salt compound, and a thiol compound.

In the case of embodiment 6, the reaction initiation, the first silicon layer etch rate, and the second silicon layer etch rate were all satisfied through a mixed composition including a hydrofluoric acid, a nitric acid, a phosphoric acid, an acetic acid, an ammonium salt compound, and a disulfide compound.

In the case of embodiment 7, the reaction initiation, the first silicon layer etch rate, and the second silicon layer etch rate were all satisfied through a mixed composition including a hydrofluoric acid, a nitric acid, a phosphoric acid, an acetic acid, an ammonium salt compound, and a phenol compound.

In the case of embodiment 8 to embodiment 17, the reaction initiation, the first silicon layer etch rate, and the second silicon layer etch rate were all satisfied through a mixed composition including a hydrofluoric acid, a nitric acid, a phosphoric acid, an acetic acid, an ammonium salt compound, and hydroxylamine.

In the case of embodiment 18 to embodiment 21, the reaction initiation, the first silicon layer etch rate, and the second silicon layer etch rate were all satisfied through a mixed composition including a hydrofluoric acid, a nitric acid, a phosphoric acid, an acetic acid, an urea compound, and hydroxylamine.

In the case of embodiment 22 and embodiment 23, the reaction initiation, the first silicon layer etch rate, and the second silicon layer etch rate were all satisfied through a mixed composition including a hydrofluoric acid, a nitric acid, a phosphoric acid, an acetic acid, a 1,2,4-triazole compound, and hydroxylamine.

Table 2 below represents a composition ratio and an evaluation result of the etching composition in a reaction of etching the silicon substrate using the etching composition according to a comparative example.

TABLE 2

| | | | | | | | Evaluation result | | |
|---|---|---|---|---|---|---|---|---|---|
| | wt % | | | | | | | First | Second |
| | Hydro- | | Phos- | | | Reaction | | silicon | silicon |
| | fluoric | Nitric | phoric | Acetic | Nitrogen | initiation | Reaction | layer | layer |
| | acid | acid | acid | acid | compound | Supplement | initiation | etch rate | etch rate |
| Compar- | 1.5 | 25.5 | 17.5 | 24.5 | Ammonium | — | Δ | ◯ | ⊚ |
| ative | | | | | fluoride 0.5 | | | | |
| Example 1 | | | | | | | | | |
| Compar- | 1.5 | 25.5 | 17.5 | 24.5 | Ammonium | Ascorbic | ⊚ | ◯ | X |
| ative | | | | | fluoride 0.5 | acid 5 | | | |
| Example 2 | | | | | | | | | |
| Compar- | 1.5 | 25.5 | 17.5 | 24.5 | — | Hydroxyl- | ⊚ | ◯ | Δ |
| ative | | | | | | amine 0.2 | | | |
| Example 3 | | | | | | | | | |
| Compar- | 13.3 | 11.1 | 10.8 | 39.4 | — | — | X | ⊚ | X |
| ative | | | | | | | | | |
| Example 4 | | | | | | | | | |

In the case of comparative example 1, it was identified that when the reaction initiator was not contained, the reaction initiation was relatively delayed.

In the case of comparative example 2, it was identified that when the content of the reaction initiator was excessive, the reaction initiation and the first silicon layer etch rate were good, but the second silicon layer etch rate was excessive.

In the case of comparative example 3, it was identified that when the nitrogen compound was not contained, the second silicon layer etch rate was excessive.

In the case of comparative example 4, it was identified that when the nitrogen compound and the reaction initiator were not contained, the reaction initiation was delayed, and the second silicon layer etch rate was excessive.

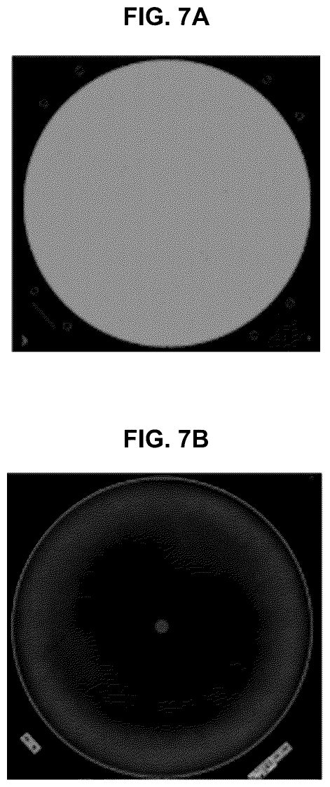

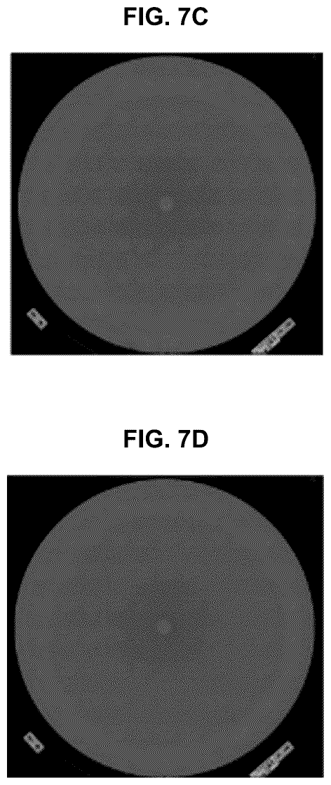

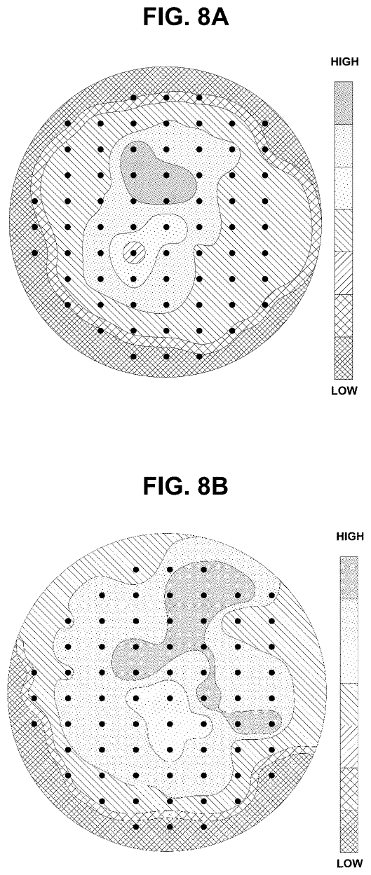

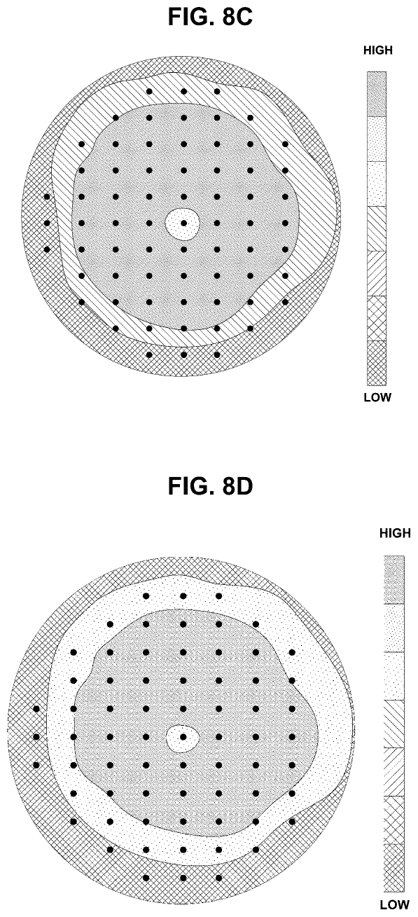

FIGS. 7A to 7D are images obtained by photographing a surface of the silicon substrate when etching is performed using an etching composition according to a comparative example and an example embodiment, and FIGS. 8A to 8D are images illustrating a height of the surface of the silicon substrate when the etching is performed using the etching composition according to the comparative example and the example of FIGS. 7A to 7D, through which roughness of the etched surface of the silicon substrate may be identified.

Here, the etching composition of FIGS. 7A and 8A and the etching composition of FIGS. 7B and 8B are etching compositions according to the comparative example, the etching compositions of FIGS. 7A and 8A do not contain the nitrogen compound and the reaction initiator and the etching compositions of FIGS. 7B and 8B do not contain the nitrogen compound. Except for the composition ratio of the etching composition, all other experimental conditions were maintained the same.

In detail, the etching composition of FIGS. 7A and 8A includes 3 wt % to 5 wt % of hydrofluoric acid, 20 wt % to 30 wt % of nitric acid, 10 wt % to 20 wt % of phosphoric acid, 40 wt % to 50 wt % of acetic acid, and a remaining balance of water, and the etching composition of FIGS. 7B and 8B includes 3 wt % to 5 wt % of hydrofluoric acid, 20 wt % to 30 wt % of nitric acid, 10 wt % to 20 wt % of phosphoric acid, 40 wt % to 50 wt % of acetic acid, 0.01 wt % to 3 wt % of a reaction initiator, and the remaining balance water. The etching composition of FIGS. 7C and 8C includes 1 wt % to 3 wt % of hydrofluoric acid, 20 wt % to 30 wt % of nitric acid, 10 wt % to 20 wt % of phosphoric acid, 20 wt % to 30 wt % of acetic acid, 0.5 wt % to 2 wt % of a nitrogen compound, 0.01 wt % to 3 wt % of a reaction initiator, and a remaining balance of water. The etching composition of FIGS. 7D and 8D is adapted to identify reproducibility by preparing a composition within substantially the same range as the etching composition of FIGS. 7C and 8C and includes 1 wt % to 3 wt % of hydrofluoric acid, 20 wt % to 30 wt % of nitric acid, 10 wt % to 20 wt % of phosphoric acid, 20 wt % to 30 wt % of acetic acid, 0.5 wt % to 2 wt % of a nitrogen compound, 0.01 wt % to 3 wt % of a reaction initiator, and a remaining balance of water.

In FIGS. 8A to 8D, patterns of each drawing corresponds to a relative height of the etched surface, and the same pattern in each drawing represents the same height.

Referring to FIGS. 7A to 7D, the color of the surface of the silicon substrate should be changed according to the initiation of the etching reaction, but in the case of the silicon substrate of FIG. 7A, the color of the surface of the silicon substrate is maintained without change. Accordingly, it may be identified that the silicon substrate is not etched or is slowly etched even when the etching is performed. In the case of FIGS. 7B to 7D, the color of the surface of the silicon substrate is changed, and accordingly, it may be identified that the etching reaction is performed.

Referring to FIGS. 8A to 8D, it may be identified that the etch uniformity is greatly changed depending on an etching composition. As can be identified in FIGS. 8A and 8B, when the etching is performed using the etching composition according to the comparative example, the etching is unevenly performed on the entire upper surface of the silicon substrate. In contrast, as can be identified in FIGS. 8C and 8D, when the etching is performed using the etching composition according to the present disclosure, the etching is uniformly performed on the entire upper surface of the silicon substrate. Further, the results obtained by re-testing using the etching composition within substantially the same range are also the same, and thus it may be identified that there is reproducibility.

In addition, as a result obtained by measuring an average thickness of the silicon substrate in FIGS. 8A to 8D, when the average thickness of the silicon substrate in FIG. 8A in which almost no etching reaction occurs is set to 1, the average thicknesses of the silicon substrates in FIGS. 8B, 8C, and 8D are 0.59, 0.34, and 0.34. Accordingly, when the etching composition according to some embodiments of the present disclosure is used, the etching is quickly performed as compared to a case in which the etching composition according to the comparative example, and thus it may be identified that the thickness of the silicon substrate after the etching is significantly decreased.

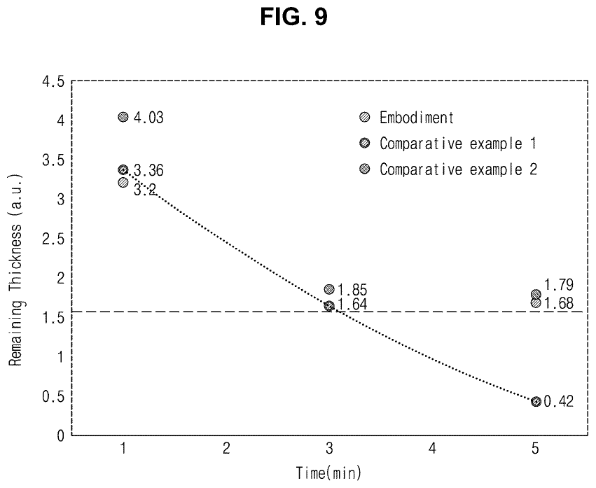

FIG. 9 is a graph depicting a thickness of a silicon layer of a substrate remaining after the etching when the etching is performed using the etching composition according to the comparative example and the example. In FIG. 9, a portion indicated by a dotted line corresponds to a boundary between the first silicon layer and the second silicon layer.

An etching composition according to an example is obtained by adding the reaction initiator at a ratio of 60:1 relative to a total composition volume to an etching composition including 1 wt % to 3 wt % of hydrofluoric acid, 20 wt % to 30 wt % of nitric acid, 10 wt % to 20 wt % of phosphoric acid, 20 wt % to 30 wt % of acetic acid, 0.5 wt % to 2 wt % of a nitrogen compound, and a remaining balance of water. An etching composition according to comparative example 1 is obtained by adding only the reaction initiator at a ratio of 60:1 relative to a total composition volume to an etching composition including 3 wt % to 5 wt % of hydrofluoric acid, 20 wt % to 30 wt % of nitric acid, 10 wt % to 20 wt % of phosphoric acid, 40 wt % to 50 wt % of acetic acid, and a remaining balance of water. An etching composition according to comparative example 2 includes 1 wt % to 3 wt % of hydrofluoric acid, 20 wt % to 30 wt % of nitric acid, 10 wt % to 20 wt % of phosphoric acid, 20 wt % to 30 wt % of acetic acid, 0.5 wt % to 2 wt % of a nitrogen compound, and a remaining balance of water and does not contain the reaction initiator.

Referring to FIG. 9, in the case of the example embodiment, it may be identified that while the first silicon layer is etched, an etch rate is decreased at a point close to an interface of the second silicon layer, and this means that etch selectivity for the first silicon layer and the second silicon layer is good. In the case of comparative example 1, similar to the example embodiment, the etch selectivity for the first silicon layer and the second silicon layer is good, but it may be identified that an initial etch rate for the first silicon is lower than that of the example embodiment. In the case of comparative example 2, even the second silicon layer is etched, and accordingly, it may be identified that the etch selectivity for the first silicon layer and the second silicon layer is not good.

According to an embodiment of the present disclosure, an etching composition used when a silicon substrate is etched is provided.

According to an embodiment of the present disclosure, an etching composition having an improved etching reaction initiation rate of a silicon substrate is provided.

According to an embodiment of the present disclosure, an etching composition having a high selectivity for different silicon layers during an etching reaction is provided.

According to an embodiment of the present disclosure, a method of treating a silicon substrate using an etching composition and a method of manufacturing an integrated circuit device using the same are provided.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims.

Accordingly, the technical scope of the present disclosure is not limited to the detailed description of the specification, but should be defined by the appended claims.

What is claimed is:

1. An etching composition for etching a silicon layer, the etching composition comprising:
an acid mixture including hydrofluoric acid, nitric acid, phosphoric acid, and acetic acid;
a reaction initiator configured to initiate a reaction between the silicon layer and the acid mixture, the reaction initiator including a reducing organic compound; and
water.

2. The etching composition of claim 1, wherein the reaction initiator reduces the nitric acid to nitrous acid.

3. The etching composition of claim 1, wherein the reducing organic compound includes a reducing sugar, an organic acid compound, a phenol compound, a thiol compound, a disulfide compound, a hydroxylamine compound, or any combinations thereof.

4. The etching composition of claim 3, wherein the organic acid compound includes an ascorbic acid, an ascorbyl palmitate, an ascorbyl glucoside, a sodium ascorbate, a potassium ascorbate, a calcium ascorbate, an erythorbic acid, a fumaric acid, a lactic acid, a citric acid, a malic acid, a butyric acid, a formic acid, a methanoic acid, an ethanoic acid, a propionic acid, a butanoic acid, a pentanoic acid, or any combinations thereof.

5. The etching composition of claim 3, wherein the reducing sugar includes glyceraldehyde, erythrose, ribose, xylose, arabinose, ribulose, glucose, fructose, mannose, galactose, maltose, lactose, cellobiose, dextrin, or any combinations thereof.

6. The etching composition of claim 3, wherein the phenol compound includes phenol, pyrocatechol, a caffeic acid, a protocatechuic acid, a ferulic acid, hydroquinone, pyrogallol, a gallic acid, propyl gallate, or any combinations thereof.

7. The etching composition of claim 3, wherein the thiol compound includes cysteine, benzylmercaptan, 2-mercaptopyridine, benzothiazole-2-thiol, gamma-glutamylcysteine, 1-phenyl-5-mercaptotetrazole, glutathione, a mercaptopropionic acid, a mercaptoacetic acid, 2-mercaptobenzimidazole, 2-mercaptobenzothiazole, 2-mercapto-1methylimidazole, or any combinations thereof.

8. The etching composition of claim 3, wherein the disulfide compound includes cystine, dibenzyl disulfide, dipyridyl disulfide, dibenzothiazyl sulfide, thiamine disulfide, allitiamine, fursultiamine, diallyl disulfide, bis(2-methyl-3-furyl)disulfide, oxidized glutathione, or any combinations thereof.

9. The etching composition of claim 1, wherein the etching composition contains 10 wt % to 30 wt % of the nitric acid, 0.5 wt % to 15 wt % of the hydrofluoric acid, 0.1 wt % to 30 wt % of the phosphoric acid, 10 wt % to 50 wt % of the acetic acid; 0.01 wt % to 3 wt % of the reaction initiator, and a remaining balance of water.

10. The etching composition of claim 9, wherein the etching composition further contains 0.5 wt % to 10 wt % of a nitrogen compound.

11. The etching composition of claim 10, wherein the nitrogen compound includes an ammonium compound, urea, a urea derivative, an azole compound, or any combinations thereof.

12. A method of treating a silicon substrate, the method comprising:
preparing the silicon substrate on which a first silicon layer doped with impurities at a first doping concentration and a second silicon layer provided as an epitaxial layer and doped with impurities at a second doping concentration different from the first doping concentration are laminated; and
selectively etching the first silicon layer with an etching composition,
wherein the etching composition includes:
an acid mixture including hydrofluoric acid, nitric acid, phosphoric acid, and acetic acid;
a reaction initiator configured to initiate a reaction between the first silicon layer and the acid mixture, the reaction initiator including a reducing organic compound; and
water.

13. The method of claim 12, wherein the reducing organic compound includes a reducing sugar, an organic acid compound, a phenol compound, a thiol compound, a disulfide compound, a hydroxylamine compound, or any combinations thereof.

14. The method of claim 12, wherein the etching composition further includes a nitrogen compound including an ammonium compound, urea, a urea derivative, an azole compound, or any combinations thereof.

15. The method of claim 12, wherein the first doping concentration is greater than the second doping concentration.

16. The method of claim 12, further comprising:
removing a portion of the first silicon layer through chemical mechanical polishing before the first silicon layer is removed through the etching composition.

17. The method of claim 12, further comprising:
removing a portion of the second silicon layer through chemical mechanical polishing after the first silicon layer is removed through the etching composition.

18. A method of manufacturing an integrated circuit device, the method comprising:
preparing a silicon substrate including a first silicon layer doped with impurities at a first doping concentration and a second silicon layer doped with impurities at a second doping concentration and having a rear surface close to the first silicon layer and a front surface close to the second silicon layer;
forming a first device pattern on the front surface of the silicon substrate;
selectively etching and removing the first silicon layer through the etching composition of claim 1; and
forming a second device pattern on the rear surface from which the first silicon layer is removed.

19. The method of claim 18, wherein the preparing of the silicon substrate includes:
forming a through-substrate via formed from an upper surface of the second silicon layer at a predetermined depth.

20. The method of claim 18, wherein the second device pattern includes a power delivery network configured to supply power to a device part.
